(19) United States
(12) Patent Application Publication
(10) Pub. No.: US 2026/0143916 A1
(43) Pub. Date: May 21, 2026

(54) PREPARATION METHOD FOR DISPLAY PANEL, DISPLAY PANEL AND ELECTRONIC DEVICE

(71) Applicants: Hefei Visionox Technology Co., Ltd., Hefei (CN); VISIONOX TECHNOLOGY INC., Jiangsu (CN)

(72) Inventors: Yuting FU, Hefei (CN); Cheng-Yi LIN, Hefei (CN); Jen-Yu LEE, Hefei (CN); Wei-Ju HUANG, Hefei (CN); Yi-Yu LAI, Hefei (CN); Quanbao LIU, Hefei (CN); Liping XU, Hefei (CN); Chung-Chun LEE, Hefei (CN)

(73) Assignees: Hefei Visionox Technology Co., Ltd., Hefei (CN); VISIONOX TECHNOLOGY INC., Jiangsu (CN)

(21) Appl. No.: 19/179,024

(22) Filed: Apr. 15, 2025

(30) Foreign Application Priority Data
Apr. 15, 2024 (CN) 202410449132.6
Jul. 31, 2024 (CN) 202411051417.0

(51) Int. Cl. H10K 59/122; H10K 59/12; H10K 59/131

(52) U.S. Cl. CPC H10K 59/122; H10K 59/1201; H10K 59/131

(57) ABSTRACT

In a preparation method for a display panel, before light-emitting devices are manufactured, a second isolation portion in an isolation structure is cleaned so that a first isolation portion has protrusion portions protruding relative to the second isolation portion and so that in the subsequent process of manufacturing the light-emitting devices, at least part of films of the light-emitting devices lap-join the protrusion portions respectively.

### CROSS-REFERENCE TO RELATED APPLICATION(S)

This application claims the priority of a Chinese Patent Application No. 202410449132.6, filed on Apr. 15, 2024, and the priority of a Chinese Patent Application No. 202411051417.0, filed on Jul. 31, 2024, the disclosures of which are incorporated herein by reference in their entireties.

### TECHNICAL FIELD

The present application relates to the field of display technology and, in particular, to a preparation method for a display panel, a display panel, and an electronic device.

### BACKGROUND

Organic light-emitting diodes (OLED) and flat-panel display devices based on technologies such as light-emitting diode (LED) have been widely applied in various consumer electronic products such as mobile phones, televisions, laptops and desktop computers, due to the advantages of high image quality, power saving, thin body and wide application range, becoming mainstream in display panels.

However, display panels still have some problems to be solved urgently.

### SUMMARY

The present application provides a preparation method for a display panel, a display panel, and an electronic device.

In a first aspect of the present application, a preparation method for a display panel is provided and includes the steps below.

A substrate is provided.

An isolation structure is formed on one side of the substrate, where a plurality of isolation openings are enclosed by the isolation structure on the substrate, and in a direction facing away from the substrate, the isolation structure includes a first isolation portion, a second isolation portion and a third isolation portion that are sequentially stacked, where an orthographic projection of the second isolation portion on the substrate is located within an orthographic projection of the third isolation portion on the substrate.

The second isolation portion in the isolation structure is cleaned to enable the first isolation portion to have a protrusion portion protruding relative to the second isolation portion in a direction facing an isolation opening of the plurality of isolation openings.

A light-emitting device is manufactured within an isolation opening of the plurality of isolation openings to enable at least part of films of the light-emitting device to lap-join the protrusion portion.

In a second aspect of the present application, a display panel is also provided. The display panel includes a substrate, an isolation structure, and light-emitting devices.

The isolation structure is located on one side of the substrate, where a plurality of isolation openings are enclosed by the isolation structure on the substrate, and in a direction facing away from the substrate, the isolation structure includes a first isolation portion, a second isolation portion and a third isolation portion that are sequentially stacked, where an orthographic projection of the second isolation portion on the substrate is located within an orthographic projection of the first isolation portion on the substrate and within an orthographic projection of the third isolation portion on the substrate.

At least part of a light-emitting device of the light-emitting devices is located within an isolation opening of the plurality of isolation openings, the light-emitting devices include a first light-emitting device and a second light-emitting device that have different emitted colors, and the plurality of isolation openings include a first isolation opening for accommodating the first light-emitting device and a second isolation opening for accommodating the second light-emitting device.

A contour line of the orthographic projection of the third isolation portion on the substrate includes a first contour line corresponding to the first isolation opening and a second contour line corresponding to the second isolation opening, and a contour line of the orthographic projection of the first isolation portion on the substrate includes a third contour line corresponding to the first isolation opening and a fourth contour line corresponding to the second isolation opening.

A first distance is present between corresponding first contour line and third contour line, and a second distance is present between corresponding second contour line and fourth contour line, where the first distance is not equal to the second distance.

In a third aspect of the present application, a display panel is also provided. The display panel includes a substrate, a pixel defining layer, an isolation structure, and light-emitting devices.

The pixel defining layer is located on one side of the substrate and includes a pixel opening.

The isolation structure is located on one side of the pixel defining layer facing away from the substrate, where a plurality of isolation openings are enclosed by the isolation structure on the substrate, and in a direction facing away from the substrate, the isolation structure includes a first isolation portion, a second isolation portion and a third isolation portion that are sequentially stacked, where an orthographic projection of the second isolation portion on the substrate is located within an orthographic projection of the first isolation portion on the substrate and within an orthographic projection of the third isolation portion on the substrate, and an orthographic projection of the pixel opening on the substrate is located within an orthographic projection of an isolation opening of the plurality of isolation openings on the substrate.

At least part of a light-emitting device of the light-emitting devices is located within an isolation opening of the plurality of isolation openings, the light-emitting devices include a first light-emitting device and a second light-emitting device that have different emitted colors, and the plurality of isolation openings include a first isolation opening for accommodating the first light-emitting device and a second isolation opening for accommodating the second light-emitting device.

Within the first isolation opening, a first spacing is present between one end of the first isolation portion facing the pixel opening and a corresponding sidewall of the pixel opening; within the second isolation opening, a second spacing is present between the end of the first isolation portion facing the pixel opening and the corresponding sidewall of the pixel opening.

The first spacing is different from the second spacing.

In a fourth aspect of the present application, a display panel is also provided. The display panel includes a substrate, an isolation structure, and light-emitting devices.

The isolation structure is located on one side of the substrate, where a plurality of isolation openings are enclosed by the isolation structure on the substrate, and in a direction facing away from the substrate, the isolation structure includes a first isolation portion, a second isolation portion and a third isolation portion that are sequentially stacked, where an orthographic projection of the second isolation portion on the substrate is located within an orthographic projection of the first isolation portion on the substrate and within an orthographic projection of the third isolation portion on the substrate.

At least part of a light-emitting device of the light-emitting devices is located within an isolation opening of the plurality of isolation openings respectively.

The isolation structure includes a seventh isolation structure and an eighth isolation structure, and at least one light-emitting device located within isolation openings on two opposite sides of the seventh isolation structure and at least one light-emitting device located within isolation openings on two opposite sides of the eighth isolation structure have different emitted colors.

On a cross section perpendicular to a plane on which the substrate is located and passing through a center connection line of two adjacent isolation openings, an orthographic projection of the third isolation portion of the seventh isolation structure on the substrate has a nineteenth length, an orthographic projection of the third isolation portion of the eighth isolation structure on the substrate has a twentieth length, an orthographic projection of the second isolation portion of the seventh isolation structure on the substrate has a twenty-first length, and an orthographic projection of the second isolation portion of the eighth isolation structure on the substrate has a twenty-second length, where the nineteenth length is the same as the twentieth length, and the twenty-first length is different from the twenty-second length.

In a fifth aspect of the present application, an electronic device is also provided. The electronic device includes a display panel prepared in any possible implementation manner in the first aspect or the display panel in any possible implementation manner in the second, third, and fourth aspects.

The present application provides the preparation method for a display panel, the display panel, and the electronic device. In the preparation method for a display panel, before the light-emitting devices are manufactured, the second isolation portion in the isolation structure is cleaned so that the first isolation portion has the protrusion portions protruding relative to the second isolation portion and so that in the subsequent process of manufacturing the light-emitting devices, at least part of films of the light-emitting devices lap-joins the protrusion portions respectively.

### BRIEF DESCRIPTION OF DRAWINGS

To illustrate technical solutions in embodiments of the present application more clearly, drawings used in the description of the embodiments are briefly described below. It is to be understood that the drawings described below illustrate part of the embodiments of the present application and are not construed as limiting the scope of the present application, and those of ordinary skill in the art may obtain other drawings based on the drawings described below on the premise that no creative work is done.

FIG. 1 is a flowchart of a preparation method for a display panel according to one or more embodiments.

FIG. 2 is a process diagram corresponding to FIG. 1.

FIG. 3 is a partial flowchart of a preparation method for a display panel according to one or more embodiments.

FIG. 4 is a process diagram corresponding to FIG. 3.

FIG. 5 is partial process diagram one according to one or more embodiments of the present application.

FIG. 6 is partial process diagram two according to one or more embodiments of the present application.

FIG. 7 is a diagram of orthographic projections of a first isolation portion and a third isolation portion at the positions of a first isolation opening and a second isolation opening.

FIG. 8 is a cross-sectional view of position AA in FIG. 7.

FIG. 9 is a diagram of orthographic projections of a first isolation portion and a third isolation portion at the positions of a first isolation opening, a second isolation opening and a third isolation opening.

FIG. 10 is a cross-sectional view of position AA in FIG. 9.

FIG. 11 is diagram one illustrating the partial film structure of a display panel according to one or more embodiments of the present application.

FIG. 12 is diagram two illustrating the partial film structure of a display panel according to one or more embodiments of the present application.

FIG. 13 is diagram three illustrating the partial film structure of a display panel according to one or more embodiments of the present application.

FIG. 14 is diagram four illustrating the partial film structure of a display panel according to one or more embodiments of the present application.

FIG. 15 is diagram five illustrating the partial film structure of a display panel according to one or more embodiments of the present application.

FIG. 16 is diagram six illustrating the partial film structure of a display panel according to one or more embodiments of the present application.

FIG. 17 is diagram seven illustrating the partial film structure of a display panel according to one or more embodiments of the present application.

FIG. 18 is diagram one illustrating the distribution of light-emitting devices according to one or more embodiments of the present application.

FIGS. 19A, 19B, and 19C are diagrams illustrating the dimensions of an isolation structure between the same type of isolation openings.

FIGS. 20A, 20B, and 20C are diagrams illustrating the dimensions of an isolation structure between different types of isolation openings.

FIG. 21 is a diagram illustrating a possible structure of an isolation structure according to one or more embodiments of the present application.

FIG. 22 is diagram eight illustrating the partial film structure of a display panel according to one or more embodiments of the present application.

FIG. 23 is diagram nine illustrating the partial film structure of a display panel according to one or more embodiments of the present application.

FIG. 24 is diagram ten illustrating the partial film structure of a display panel according to one or more embodiments of the present application.

FIG. 25 is diagram eleven illustrating the partial film structure of a display panel according to one or more embodiments of the present application.

FIG. 26 is diagram two illustrating the distribution of light-emitting devices according to one or more embodiments of the present application.

FIGS. 27A and 27B are diagrams illustrating the dimensions of an isolation structure between adjacent isolation openings.

### DETAILED DESCRIPTION

To illustrate the object, the technical solutions and advantages of embodiments of the present application more clearly, the technical solutions of the embodiments of the present application are described clearly and completely in conjunction with the drawings of the embodiments of the present application. Apparently, the embodiments described below are part, not all, of the embodiments of the present application. Assemblies of the embodiments of the present applications described and illustrated in the drawings herein can be generally arranged and designed in various different configurations.

In the description of the present application, it is to be noted that orientations or positional relationships indicated by terms such as “center”, “above” “below”, “vertical”, “horizontal”, “inside” and “outside” are based on orientations or positional relationships illustrated in the drawings or orientations or positional relationship that products of the present application are usually used in. These orientations or positional relationships are for facilitating and simplifying the description of the present application and do not indicate or imply that an apparatus or element referred to must have a specific orientation and must be configured and operated in the specific orientation. Therefore, these orientations or positional relationships are not to be construed as limiting the present application. Moreover, terms “first”, “second” and “third” are for distinguishing the description and are not to be construed as indicating or implying relative importance.

It is to be noted that if not in collision, different features in the embodiments of the present application may be combined with each other.

Improving the density of light-emitting devices in display panels (that is, the pixel density) is an important way to improve the display effects. However, the display panels currently manufactured using fine metal mask (FMM) technology cannot have the density of the light-emitting devices further increased due to technical limitations. After long-term research, the inventors have found that to solve the technical problem that the density of light-emitting devices cannot be further increased, isolation structures are disposed in some display panels respectively. When entire layers of light-emitting material layers and cathodes are evaporated, the light-emitting material layers and the cathodes can be disconnected at the isolation structures. Light-emitting devices having different colors can be formed in different isolation openings through multiple evaporations and multiple etching processes, that is, the light-emitting devices are patterned.

Patent CN118251982A, Patent 202410864269.8, Patent PCT/CN2024/098407, Patent PCT/CN2024/102783, Patent PCT/CN2024/098217, Patent PCT/CN2024/100935, Patent PCT/CN2024/102785, Patent PCT/CN2024/099419, Patent PCT/CN2024/099072 and Patent CN116685174A record related technical solutions of isolation structure (partition structure or isolation column) and encapsulation layer, the disclosures of which are incorporated herein by reference in their entireties for reference.

The inventors have found that the preceding display panels may vary to a certain extent in the display uniformity, thereby affecting the overall display effects of the display panels. After analyzing the causes behind the preceding technical problems, the inventors have found that the main reason is poor lap joints between the light-emitting devices and the isolation structures.

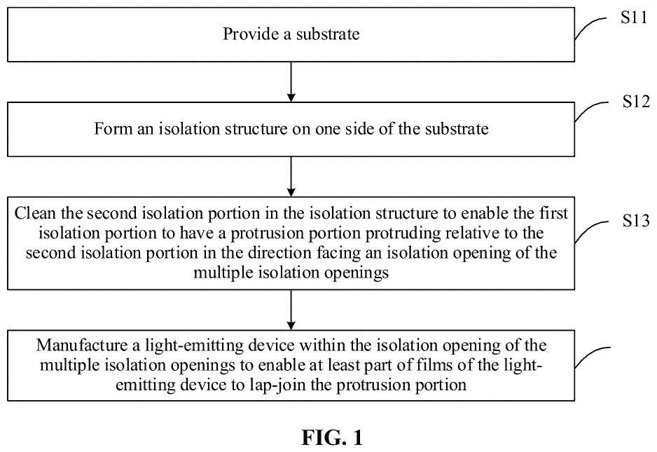

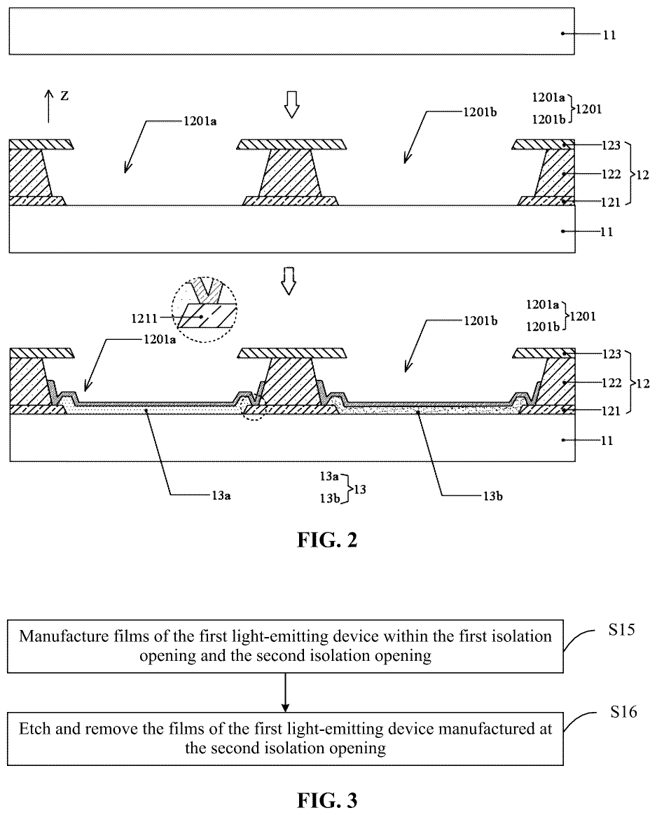

Referring to FIGS. 1 and 2, FIG. 1 is a flowchart of a preparation method for a display panel according to one or more embodiments, and FIG. 2 is a process diagram corresponding to FIG. 1. The preparation method for a display panel provided in this embodiment is described in detail below in conjunction with FIGS. 1 and 2.

In S11, a substrate 11 is provided.

In this embodiment, the substrate 11 is a multilayer structure and at least includes multiple conductive layers and one or more insulating layers, and at least one of the insulating layers is located between adjacent conductive layers. Pixel circuits for providing drive signals for light-emitting devices are formed in the substrate 11. The multiple conductive layers may be metal conductive layers.

In S12, an isolation structure 12 is formed on one side of the substrate 11.

In one or more embodiments, the isolation structure 12 is provided with multiple isolation openings 1201. In the direction facing away from the substrate 11 (Z direction in the figure), the isolation structure 12 includes a first isolation portion 121, a second isolation portion 122, and a third isolation portion 123 that are sequentially stacked. The orthographic projection of the second isolation portion 122 on the substrate 11 is located within the orthographic projection of the third isolation portion 123 on the substrate 11.

In S13, the second isolation portion 122 in the isolation structure 12 is cleaned to enable the first isolation portion 121 to have a protrusion portion 1211 protruding relative to the second isolation portion 122 in the direction facing an isolation opening 1201.

In S14, a light-emitting device 13 is manufactured within an isolation opening 1201 of the multiple isolation openings 1201 to enable at least part of films of the light-emitting device 13 to lap-join the protrusion portion 1211.

In one or more embodiments, the films of the light-emitting device 13 are manufactured within a respective isolation opening 1201. The at least part of the films of the light-emitting device 13 lap-join a respective protrusion portion 1211. For example, a light-emitting material layer of the light-emitting device 13 and an electrode (which are referred to as second electrodes hereinafter) located on a side of the light-emitting material layer facing away from the substrate 11 may lap-join the respective protrusion portion 1211. The at least part of the films of the light-emitting device 13 may also lap-join the second isolation portion 122 via the respective protrusion portion 1211 respectively. Exemplarily, a second electrode of the light-emitting device 13 may lap-join the second isolation portion 122 via the respective protrusion portion 1211. “Lap-joint” herein means connection or contact. For example, the second electrode of the light-emitting device 13 is connected to the respective protrusion portion 1211.

In the preceding solution, before the light-emitting device 13 is manufactured, the second isolation portion 122 in the isolation structure 12 is cleaned so that the first isolation portion 121 can have the protrusion portion 1211 protruding relative to the second isolation portion 122 and so that in the subsequent process of manufacturing the light-emitting device 13, the at least part of the films of the light-emitting device 13 can lap-join the protrusion portion 1211, thereby improving the lap-joint effect of the light-emitting device 13 and the isolation structure 12 and improving the display effect of the display panel 1.

In one or more embodiments, the light-emitting devices 13 include a first light-emitting device 13a and a second light-emitting device 13b that have different emitted colors, and the multiple isolation openings 1201 include a first isolation opening 1201a and a second isolation opening 1201b. The first light-emitting device 13a and the second light-emitting device 13b being manufactured in a sequential order is used as an example below for illustration. Before the first light-emitting device 13a is manufactured, the first isolation portion 121 protrudes relative to the second isolation portion 122 in an isolation opening 1201 of the multiple isolation openings 1201. Specifically, in the first isolation opening 1201a, the first isolation portion 121 has a first protrusion portion 12111 protruding relative to the second isolation portion 122.

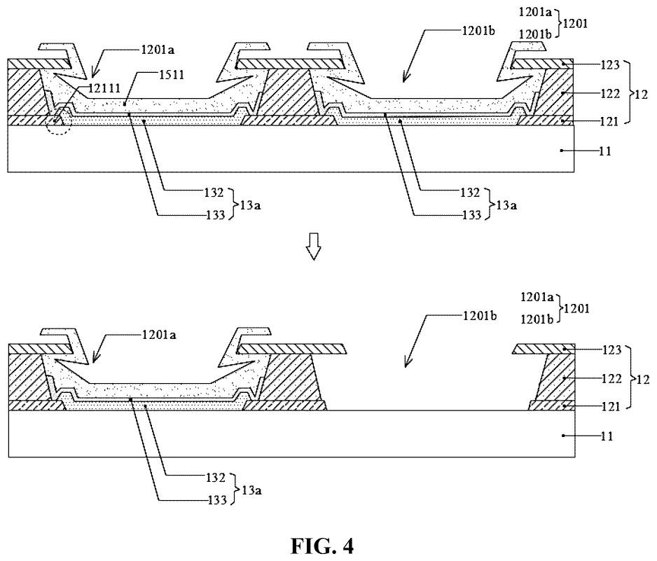

Referring to FIGS. 3 and 4, before S13, the preparation method for a display panel provided in one or more embodiments further includes the steps below.

In S15, films of the first light-emitting device 13a are manufactured within the first isolation opening 1201 a and the second isolation opening 1201b.

Exemplarily, a light-emitting material layer 132 of the first light-emitting device 13a and a second electrode 133 of the first light-emitting device 13a may be manufactured. After the first light-emitting device 13a is manufactured, an encapsulation unit 1511 of the first light-emitting device 13a may also be manufactured. Within the first isolation opening 1201a, at least part of the films of the first light-emitting device 13a lap-joins the first protrusion portion 12111. Exemplarily, the light-emitting material layer 132 of the first light-emitting device 13a and the second electrode 133 of the first light-emitting device 13a lap-join the first protrusion portion 12111 separately, or the second electrode 133 of the first light-emitting device 13a lap-joins the first protrusion portion 12111.

In S16, the films of the first light-emitting device 13a manufactured at the second isolation opening 1201b are etched and removed.

In this step, the films of the first light-emitting device 13a manufactured within the second isolation opening 1201b may be removed. Exemplarily, the light-emitting material layer 132 of the first light-emitting device 13a, the second electrode 133 of the first light-emitting device 13a and the encapsulation unit 1511 of the first light-emitting device 13a that are manufactured within the second isolation opening 1201b are removed so that the films of the first light-emitting device 13a are just remained within the first isolation opening 1201a.

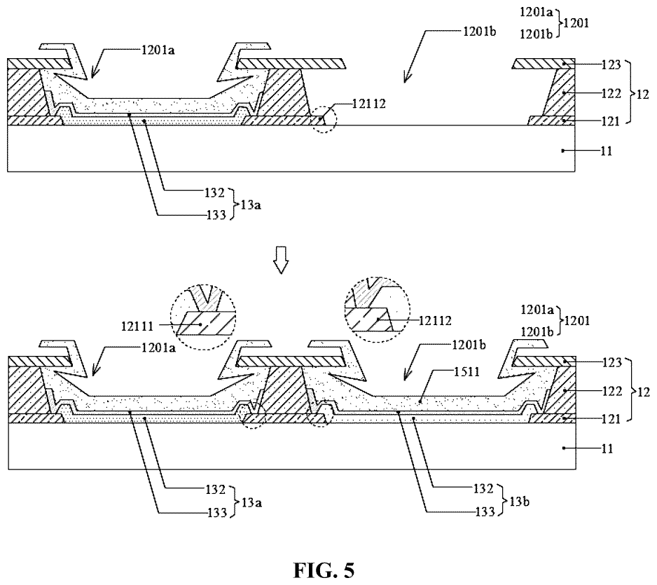

In one or more embodiments, referring to FIG. 5, S13 may be implemented in the following manner.

The second isolation portion 122 on the periphery of the second isolation opening 1201b is cleaned using a cleaning solution to enable the first isolation portion 121 to have a second protrusion portion 12112 protruding relative to the second isolation portion 122 within the second isolation opening 1201b. The cleaning solution may be an acidic etching solution or an alkaline etching solution and may be selected according to the materials of the second isolation portion 122 and the first isolation portion 121. The etching speed of the cleaning solution on the second isolation portion 122 is greater than the etching speed of the cleaning solution on the first isolation portion 121. In this manner, the first isolation portion 121 is protruding relative to the second isolation portion 122 after cleaning is performed using the cleaning solution.

In one or more embodiments, referring to FIG. 5, S14 may be implemented in the following manner.

Films of the second light-emitting device 13b are manufactured within the second isolation opening 1201b. Exemplarily, a light-emitting material layer 132 of the second light-emitting device 13b and a second electrode 133 of the second light-emitting device 13b may be manufactured. After the second electrode 133 of the second light-emitting device 13b is manufactured, an encapsulation unit 1511 of the second light-emitting device 13b may also be manufactured. Within the second isolation opening 1201b, at least part of the films of the second light-emitting device 13b lap-joins the second protrusion portion 12112. Exemplarily, the light-emitting material layer 132 of the second light-emitting device 13b and the second electrode 133 of the second light-emitting device 13b lap-join the second protrusion portion 12112 separately, or the second electrode 133 of the second light-emitting device 13b lap-joins the second protrusion portion 12112.

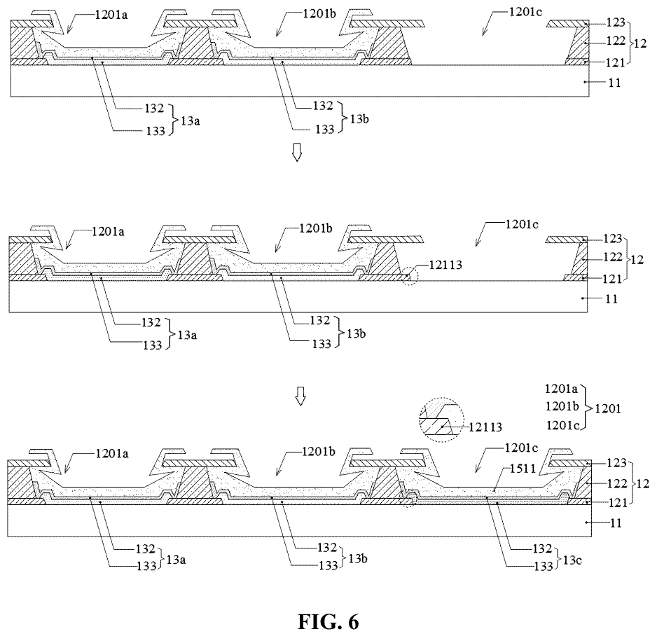

Further, in one or more embodiments, the light-emitting devices 13 further include a third light-emitting device 13c having an emitted color different from the emitted color of the first light-emitting device 13a and the emitted color of the second light-emitting device 13b. The multiple isolation openings 1201 further include a third isolation opening 1201c, and the third light-emitting device 13c is manufactured within the third isolation opening 1201c. After the second light-emitting device 13b is manufactured within the second isolation opening 1201b, referring to FIG. 6, S15 may further include the following steps.

First, the films of the second light-emitting device 13b manufactured at the third isolation opening 1201c are etched and removed.

Exemplarily, the light-emitting material layer 132 of the second light-emitting device 13b, the second electrode 133 of the second light-emitting device 13b and the encapsulation unit 1511 of the second light-emitting device 13b that are manufactured within the third isolation opening 1201c are removed.

Second, the second isolation portion 122 on the periphery of the third isolation opening 1201c is cleaned using the etching solution to enable the first isolation portion 121 to have a third protrusion portion 12113 protruding relative to the second isolation portion 122 within the third isolation opening 1201c. This process is similar to the preceding process of cleaning the second isolation portion 122 on the periphery of the second isolation opening 1201b to obtain the second protrusion portion 12112, and details are not repeated herein.

In one or more embodiments, referring to FIG. 6, S16 may be implemented in the following manner.

Films of the third light-emitting device 13c are manufactured within the third isolation opening 1201c, and at least part of the films manufactured within the third isolation opening 1201c may at least include a light-emitting material layer 132, a second electrode 133, and an encapsulation unit 1511. Within the third isolation opening 1201c, the at least part of the films of the third light-emitting device 13c lap-joins the third protrusion portion 12113. Exemplarily, the light-emitting material layer 132 of the third light-emitting device 13c and the second electrode 133 of the third light-emitting device 13c lap-join the third protrusion portion 12113 separately, or the second electrode 133 of the third light-emitting device 13c lap-joins the third protrusion portion 12113.

In the technical solution provided in the preceding embodiment, between the step of etching and removing films of a light-emitting device 13 previously manufactured within an isolation opening 1201 (such as the second isolation opening 1201b or the third isolation opening 1201c) and the step of manufacturing films of a new light-emitting device within the isolation opening, the step of cleaning the second isolation portion 122 within the isolation opening 1201 is added. In this manner, the shortening of the protrusion portion of the first isolation portion 121 relative to the second isolation portion 122, caused by etching and removing the films formed during the manufacturing of the previous light-emitting device 13, is avoided, and the affecting of the lap-joint of the light-emitting device 13 later manufactured and the isolation structure 12 due to the shortening the protrusion portion is reduced, thereby improving the display effect of the display panel 1.

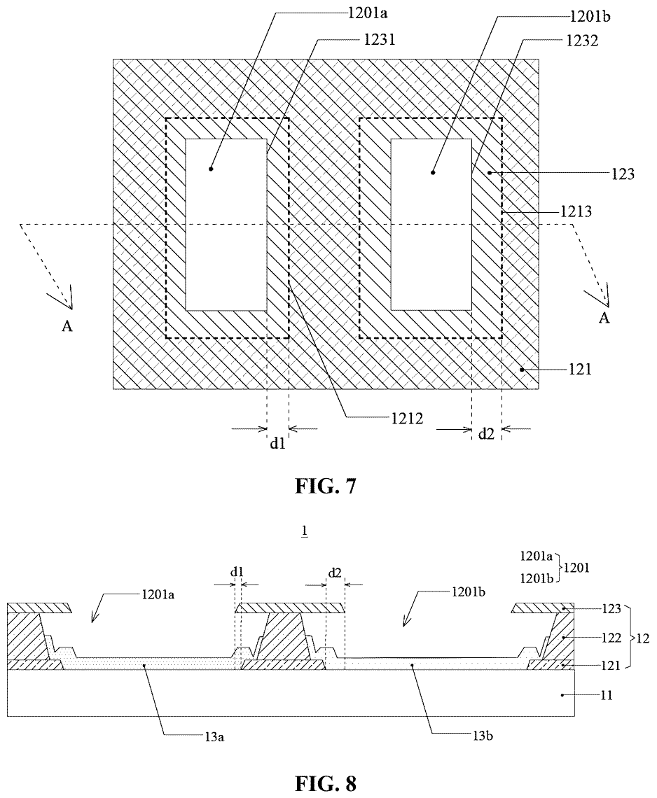

Based on the same inventive concept, this embodiment further provides a display panel. The display panel may be manufactured using the preparation method provided in the preceding embodiment. Referring to FIGS. 7 and 8, FIG. 7 is a diagram of orthographic projections of a first isolation portion and a third isolation portion at the positions of a first isolation opening and a second isolation opening, and FIG. 8 is a cross-sectional view of position AA in FIG. 7. In this embodiment, the display panel 1 includes a substrate 11, an isolation structure 12 and light-emitting devices 13. The substrate 11 is a multilayer structure and at least includes multiple conductive layers and one or more insulating layers, and at least one of the insulating layers is located between adjacent conductive layers. Pixel circuits for providing drive signals for the light-emitting devices are formed in the substrate 11. The multiple conductive layers may be metal conductive layers.

The isolation structure 12 is located on one side of the substrate 11 and provided with multiple isolation openings 1201. In the direction facing away from the substrate 11, the isolation structure 12 includes a first isolation portion 121, a second isolation portion 122, and a third isolation portion 123 that are sequentially stacked. The orthographic projection of the second isolation portion 122 on the substrate 11 is located within the orthographic projection of the first isolation portion 121 on the substrate 11 and within the orthographic projection of the third isolation portion 123 on the substrate 11. The orthographic projection of the first isolation portion 121 on the substrate 11 is located within the orthographic projection of the third isolation portion 123 on the substrate 11. On the cross section perpendicular to the plane on which the substrate 11 is located and in the direction of a center connection line of adjacent isolation openings (the direction of a section line AA in FIG. 7), the cross-sectional shape of the isolation structure 12 is I-shaped.

At least part of a light-emitting device 13 of the light-emitting devices 13 is located within an isolation opening 1201 of the multiple isolation openings 1201 respectively. The light-emitting devices 13 include a first light-emitting device 13a and a second light-emitting device 13b that have different emitted colors. The multiple isolation openings 1201 include a first isolation opening 1201a and a second isolation opening 1201b. At least part of the first light-emitting device 13a is accommodated within the first isolation opening 1201a, and at least part of the second light-emitting device 13b is accommodated within the second isolation opening 1201b.

In one or more embodiments, a contour line of the orthographic projection of the third isolation portion 123 on the substrate 11 includes a first contour line 1231 corresponding to the first isolation opening 1201 a and a second contour line 1232 corresponding to the second isolation opening 1201b. A contour line of the orthographic projection of the first isolation portion 121 on the substrate 11 includes a third contour line 1212 corresponding to the first isolation opening 1201a and a fourth contour line 1213 corresponding to the second isolation opening 1201b.

A first distance d1 is present between corresponding first contour line 1231 and third contour line 1212. A second distance d2 is present between corresponding second contour line 1232 and fourth contour line 1213. The first distance dl is not equal to the second distance d2. The corresponding contour lines refer to contour lines located on the same side of the same isolation opening 1201 and may be parallel to each other. For example, the first distance d1 between the corresponding first contour line 1231 and third contour line 1212 refers to the distance between the first contour line 1231 and the third contour line 1212 that are parallel to each other and located on the same side of the first isolation opening 1201a.

As can be seen from the preparation method for a display panel in the preceding embodiment, the isolation structure 12 around the second isolation opening 1201b is etched once to remove the films of the light-emitting device in the second isolation opening, the first isolation portion 121 in the second isolation opening 1201b is partially etched, but the third isolation portion 123 is basically not affected by the etching solution, resulting in the previously described first distance d1 and second distance d2 being unequal. In this embodiment, the first distance d1 is less than the second distance d2.

In one or more embodiments, the material of the first isolation portion 121 includes molybdenum or titanium, and/or the material of the second isolation portion 122 includes aluminum, silver, or copper, and/or the material of the third isolation portion 123 includes titanium or molybdenum. Optionally, the material of the first isolation portion 121 includes molybdenum, the material of the second isolation portion 122 includes aluminum, and the material of the third isolation portion 123 includes titanium.

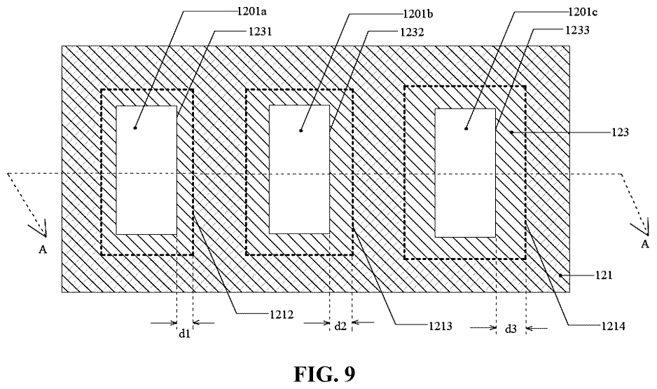

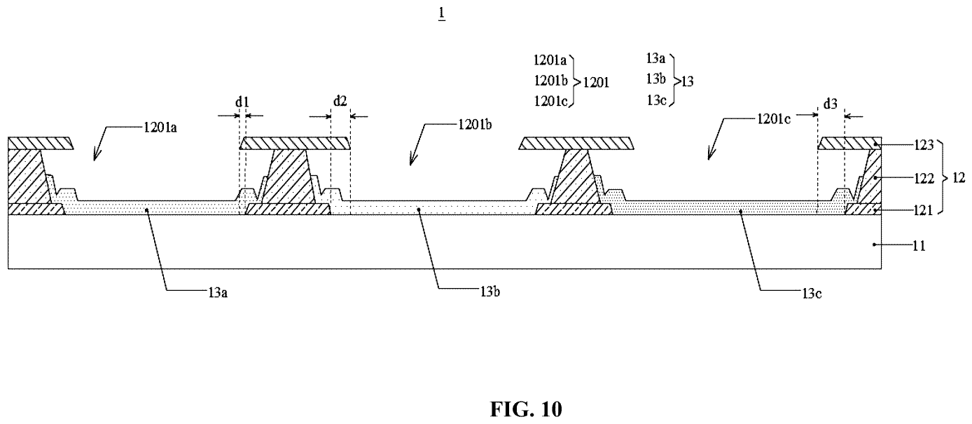

In one or more possible embodiments, referring to FIGS. 9 and 10, the light-emitting devices 13 further include a third light-emitting device 13c. The third light-emitting device 13c has an emitted color different from the emitted colors of the first light-emitting device 13a and the second light-emitting device 13b. The multiple isolation openings 1201 further include a third isolation opening 1201c, and at least part of the third light-emitting device 13c is located within the third isolation opening 1201c. The contour line of the orthographic projection of the third isolation portion 123 on the substrate 11 includes a fifth contour line 1233 corresponding to the third isolation opening 1201c, and the contour line of the orthographic projection of the first isolation portion 121 on the substrate 11 includes a sixth contour line 1214 corresponding to the third isolation opening 1201c. A third distance d3 is present between corresponding fifth contour line 1233 and sixth contour line 1214. The first distance d1, the second distance d2, and the third distance d3 are not equal.

Similarly, as can be learned from the preparation method for a display panel in the preceding embodiment, the isolation structure 12 around the third isolation opening 1201c is etched twice to remove the films of the light-emitting devices in the third isolation opening 1201c, the first isolation portion 121 in the third isolation opening 1201c is etched twice, but the third isolation portion 123 is basically not affected by the etching solution, resulting in the previously described first distance d1, second distance d2, and third distance d3 being unequal. In this embodiment, the first distance d1, the second distance d2, and the third distance d3 increase sequentially.

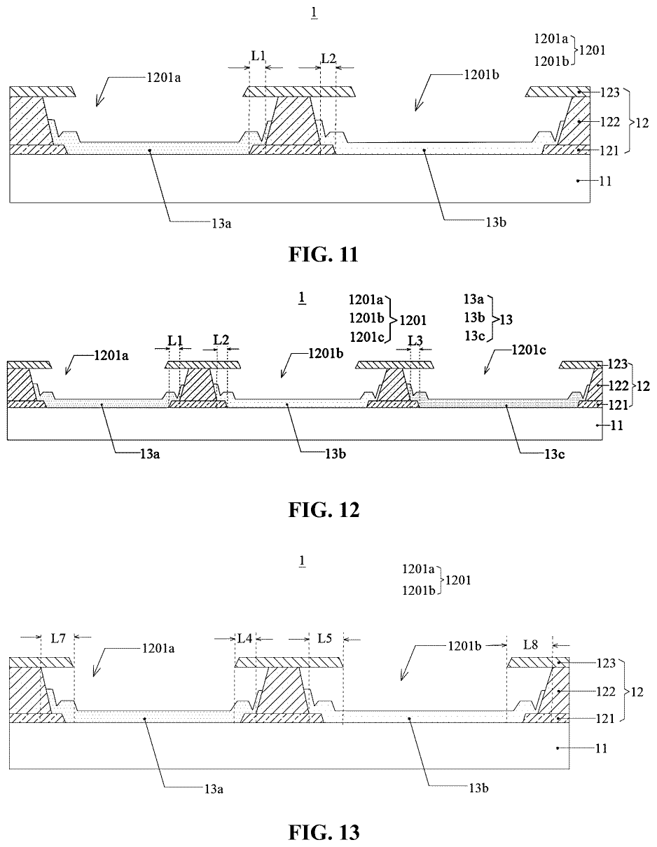

In one or more embodiments, referring to FIG. 11, within the first isolation opening 1201a, the first isolation portion 121 has a first protrusion length L1 relative to the second isolation portion 122, and within the second isolation opening 1201b, the first isolation portion 121 has a second protrusion length L2 relative to the second isolation portion 122. The first protrusion length L1 and the second protrusion length L2 are each less than or equal to 0.3 μm or 0.2 μm. The first protrusion length L1 and the second protrusion length L2 are each greater than or equal to 0.1 μm. Exemplarily, the first protrusion length L1 and the second protrusion length L2 each are 0.1 μm, 0.105 μm, 0.124 μm, 0.155 μm, 0.186 μm, 0.214 μm, 0.246 μm, 0.273 μm, 0.289 μm, 0.295 μm, or 0.3 μm. Optionally, the first protrusion length L1 may be greater than or equal to the second protrusion length L2. The preceding configuration ensures the equivalent lap-joint lengths of the first light-emitting device 13a and the second light-emitting device 13b with the first isolation portion 121 and ensures equivalent lap-joint resistances of the first light-emitting device 13a and the second light-emitting device 13b with the first isolation portion 121.

In one or more possible embodiments, referring to FIG. 12, within the third isolation opening 1201c, the first isolation portion 121 has a third protrusion length L3 relative to the second isolation portion 123. The relationship among the first protrusion length L1, the second protrusion length L2 and the third protrusion length L3 may be that the first protrusion length L1 is greater than or equal to the second protrusion length L2, and the second protrusion length L2 is equal to the third protrusion length L3; or the first protrusion length LI is equal to the third protrusion length L3 and greater than or equal to the second protrusion length L2; or the first protrusion length L1, the second protrusion length L2 and the third protrusion length L3 are equal. The preceding configuration ensures the equivalent lap-joint lengths of the first light-emitting device 13a, the second light-emitting device 13b and the third light-emitting device 13c with the first isolation portion 121 and ensures equivalent lap-joint resistances of the first light-emitting device 13a, the second light-emitting device 13b and the third light-emitting device 13c with the first isolation portion 121.

In one or more embodiments, referring to FIG. 13, within the first isolation opening 1201a, the third isolation portion 123 has a fourth protrusion length LA relative to the bottom on one side of the second isolation portion 122 facing the substrate 11, and within the second isolation opening 1201b, the third isolation portion 123 has a fifth protrusion length L5 relative to the bottom on the side of the second isolation portion 122 facing the substrate 11. Since the second isolation portion 122 within the second isolation opening 1201b is cleaned once, the fourth protrusion length LA is not equal to the fifth protrusion length L5. In this embodiment, the fourth protrusion length LA is less than the fifth protrusion length L5. The fourth protrusion length L4 ranges from 0.1 μm to 0.6 μm, and the fifth protrusion length L5 ranges from 0.2 μm to 0.9 μm. Exemplarily, the fourth protrusion length LA includes 0.1 μm, 0.15 μm, 0.19 μm, 0.235 μm, 0.28 μm, 0.36 μm, 0.42 μm, 0.49 μm, 0.52 μm, 0.55 μm, or 0.6 μm, and the fifth protrusion length L5 includes 0.2 μm, 0.22 μm, 0.26 μm, 0.35 μm, 0.42 μm, 0.51 μm, 0.64 μm, 0.75 μm, 0.82 μm, 0.88 μm, or 0.9 μm.

Similarly, within the first isolation opening 1201a, the third isolation portion 123 has a seventh protrusion length L7 relative to the top on one side of the second isolation portion 122 facing away from the substrate 11, and within the second isolation opening 1201b, the third isolation portion 123 has an eighth protrusion length L8 relative to the top on the side of the second isolation portion 122 facing away from the substrate 11. Since the second isolation portion 122 within the second isolation opening 1201b is cleaned once, the seventh protrusion length L7 is not equal to the eighth protrusion length L8. In this embodiment, the seventh protrusion length L7 is less than the eighth protrusion length L8.

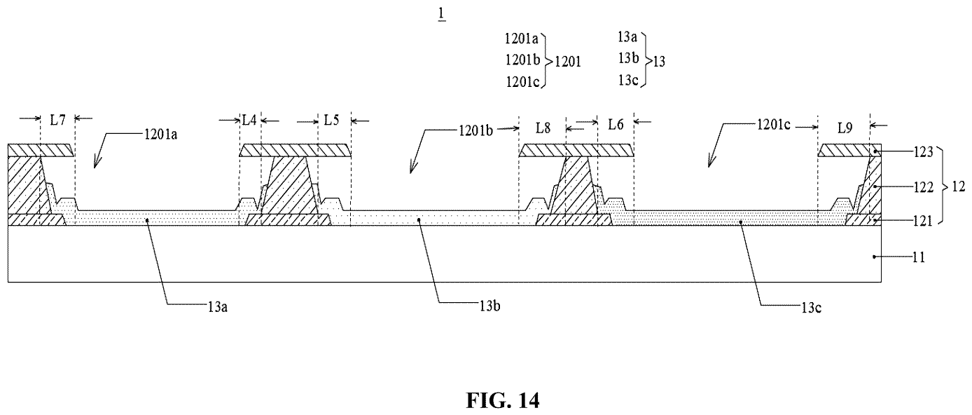

In one or more possible embodiments, referring to FIG. 14, within the third isolation opening 1201c, the third isolation portion 123 has a sixth protrusion length L6 relative to the bottom on the side of the second isolation portion 122 facing the substrate 11 and has a ninth protrusion length L9 relative to the top on the side of the second isolation portion 122 facing away from the substrate 11. The sixth protrusion length L6 ranges from 0.3 μm to 1.2 μm. Exemplarily, the sixth protrusion length L6 includes 0.3 μm, 0.42 μm, 0.56 μm, 0.65 μm, 0.72 μm, 0.81 μm, 0.94 μm, 1.05 μm, 1.12 μm, or 1.2 μm.

In one or more embodiments, the fourth protrusion length LA, the fifth protrusion length L5, and the sixth protrusion length L6 increase sequentially, and the seventh protrusion length L7, the eighth protrusion length L8, and the ninth protrusion length L9 also increase sequentially.

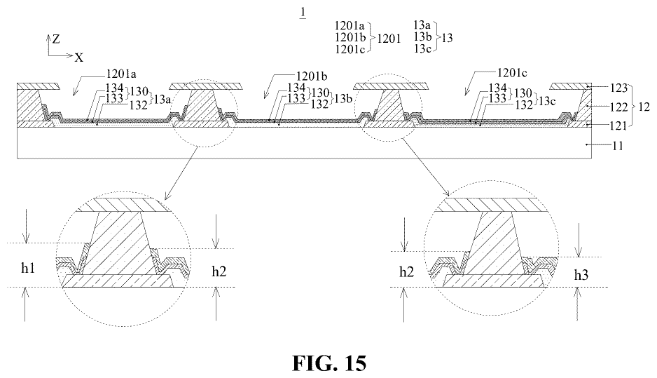

In one or more embodiments, referring to FIG. 15, in the direction facing away from the substrate 11, a light-emitting device 13 includes a light-emitting material layer 132 and a device function layer 130, and the device function layer 130 includes at least one of a second electrode 133 and a light extraction layer 134. Exemplarily, the device function layer 130 includes the second electrode 133, or the device function layer 130 includes the second electrode 133 and the light extraction layer 134, or the device function layer 130 includes the light extraction layer 134. When the device function layer 130 includes the light extraction layer 134, the light-emitting device 13 also includes the second electrode 133 located between the light-emitting material layer 132 and the device function layer 130.

The device function layer 130 lap-joins one side of the second isolation portion 122 facing the multiple isolation openings 1201. In the direction perpendicular to the plane on which the substrate 11 is located (the Z direction in the figure), the distance from the highest point at which the device function layer 130 lap-joins the second isolation portion 122 to the plane on which the substrate 11 is located is the lap-joint height of the device function layer 130 and the second isolation portion 122. When the device function layer 130 includes the second electrode 133 or the light extraction layer 134, the lap-joint height of the device function layer 130 and the second isolation portion 122 is the distance from the highest point at which the second electrode 133 or the light extraction layer 134 lap-joins the second isolation portion 122 to the plane on which the substrate 11 is located. When the device function layer 130 includes the second electrode 133 and the light extraction layer 134, the lap-joint height of the device function layer 130 and the second isolation portion 122 is the distance from the highest point at which the second electrode 133 and the light extraction layer 134 lap-join the second isolation portion 122 to the plane on which the substrate 11 is located.

Referring to FIG. 15, the lap-joint height of the device function layer 130 of the first light-emitting device 13a and the second isolation portion 122 is a first lap-joint height h1, and the lap-joint height of the device function layer 130 of the second light-emitting device 13b and the second isolation portion 122 is a second lap-joint height h2. Since the second isolation portion 122 around the second isolation opening 1201b is cleaned once, a portion of the second isolation portion 122 is side-etched laterally (the X direction in the figure), resulting in the first lap-joint height h1 and the second lap-joint height h2 being different. In this embodiment, the first lap-joint height h1 is greater than the second lap-joint height h2.

In one or more possible embodiments, at least two of the first lap-joint height h1, the second lap-joint height h2, and the third lap-joint height h3 are different. Referring to FIG. 15, the device function layer 130 of the third light-emitting device 13c has a third lap-joint height h3 with the second isolation portion 122. Since the second isolation portion 122 around the second isolation opening 1201b is cleaned once, and the second isolation portion 122 around the third isolation opening 1201c is cleaned twice, the lateral side-etching amount of the second isolation portion 122 around the third isolation structure 1201c is greater than the lateral side-etching amount of the second isolation portion 122 around the second isolation structure 1201b, resulting in the first lap-joint height h1, the second lap-joint height h2 and the third lap-joint height h3 being different. In this embodiment, the first lap-joint height h1, the second lap-joint height h2, and the third lap-joint height h3 decrease sequentially.

Further, the device function layer 130 of the first light-emitting device 13a and the second isolation portion 122 have a first lap-joint area, and the device function layer 130 of the second light-emitting device 13b and the second isolation portion 122 have a second lap-joint area. The lap-joint area is positively correlated with the lap-joint height. Since the first lap-joint height h1 is different from the second lap-joint height h2, the first lap-joint area is also different from the second lap-joint area. At least two of the first lap-joint area, the second lap-joint area, and a third lap-joint area are different. Optionally, the first lap-joint area is greater than the second lap-joint area. In this embodiment, the device function layer 130 of the third light-emitting device 13c and the second isolation portion 122 have the third lap-joint area. Since the first lap-joint height h1, the second lap-joint height h2, and the third lap-joint height h3 are different, the first lap-joint area, the second lap-joint area, and the third lap-joint area are also different. Optionally, the first lap-joint area, the second lap-joint area, and the third lap-joint area decrease sequentially. In this embodiment, the first isolation opening 1201a, the second isolation opening 1201b, and the third isolation opening 1201c are formed at the same time.

In another possible embodiment, the first isolation opening 1201a and the second isolation opening 1201b are formed at the same time, and after the first light-emitting device 13a is prepared within the first isolation opening 1201a, and the second light-emitting device 13b is prepared within the second isolation opening 1201b, the third isolation opening 1201c is formed. In one or more embodiments, the number of times of cleaning the second isolation portion 122 around the first isolation opening 1201a and the number of times of cleaning the second isolation portion 122 around the third isolation opening 1201c are each less than the number of times of cleaning the second isolation portion 122 around the second isolation opening 1201b. For example, the second isolation portion 122 around the first isolation opening 1201a and the second isolation portion 122 around the third isolation opening 1201c are not cleaned, but the second isolation portion 122 around the second isolation opening 1201b is cleaned once. In this case, the first lap-joint height h1 is the same as the third lap-joint height h3 and greater than the second lap-joint height h2. The first lap-joint area is the same as the third lap-joint area and greater than the second lap-joint area.

In the present application, when the difference between two objects is within the process error range, the two objects may be considered “the same”.

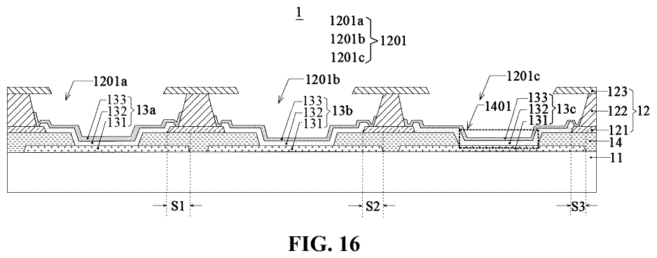

Referring to FIG. 16, the light-emitting device 13 includes a first electrode 131 connected to a pixel circuit in the substrate 11. The display panel 1 further includes a pixel defining layer 14 located on the side of the substrate 11, the isolation structure 12 is located on one side of the pixel defining layer 14 facing away from the substrate 11, and the pixel defining layer 14 includes one or more pixel openings 1401. A pixel opening 1401 exposes the first electrode 131 of a light-emitting device 13. The orthographic projection of the pixel opening 1401 on the substrate 11 is located within the orthographic projection of an isolation opening 1201 on the substrate 11. The pixel defining layer 14 may be made of an organic material or an inorganic material. When the pixel defining layer 14 is made of the inorganic material, the pixel defining layer 14 may be a single film structure of silicon oxide or silicon nitride, or a multi-film structure stacked by silicon oxide and silicon nitride. In this embodiment, the first electrode 131 may be an anode of the light-emitting device 13, and the second electrode 133 may be a cathode of the light-emitting device 13.

The orthographic projection of the first electrode 131 of the light-emitting device 13 on the substrate 11 partially overlaps the orthographic projection of the first isolation portion 121 on the substrate 11. On the cross section perpendicular to the plane on which the substrate 11 is located and passing through a center connection line of two adjacent isolation openings 1201, the orthographic projection of the first electrode 131 of the first light-emitting device 13a on the substrate 11 and the orthographic projection of the first isolation portion 121 on the substrate 11 have a first overlapping length S1, and the orthographic projection of the first electrode 131 of the second light-emitting device 13b on the substrate 11 and the orthographic projection of the first isolation portion 121 on the substrate 11 have a second overlapping length S2. In the process of manufacturing the light-emitting devices 13, the isolation structure 12 around the second isolation opening 1201b is affected by the patterned etching of the light-emitting devices once (that is, the films of the first light-emitting device 13a manufactured within the second isolation opening 1201b are etched and removed), so the first isolation portion 121 around the second isolation opening 1201b is partially etched and shortened, resulting in the first overlapping length S1 and the second overlapping length S2 being different. In this embodiment, the first overlapping length S1 is greater than the second overlapping length S2.

Referring to FIG. 16, on the cross section perpendicular to the plane on which the substrate 11 is located and passing through the center connection line of the two adjacent isolation openings 1201, the orthographic projection of the first electrode 131 of the third light-emitting device 13c on the substrate 11 and the orthographic projection of the first isolation portion 121 on the substrate 11 have a third overlapping length S3. At least two of the first overlapping length S1, the second overlapping length S2, and the third overlapping length S3 are different.

In one or more possible embodiments, in the process of manufacturing the light-emitting devices 13, the isolation structure 12 around the second isolation opening 1201b is affected by the patterned etching of the light-emitting devices once (that is, the films of the first light-emitting device 13a manufactured within the second isolation opening 1201b are etched and removed), and the isolation structure 12 around the third isolation opening 1201c is affected by the patterned etching of the light-emitting devices twice (that is, the films of the first light-emitting device 13a manufactured within the third isolation opening 1201c are etched and removed, and the films of the second light-emitting device 13b manufactured within the third isolation opening 1201c are etched and removed), so the first isolation portion 121 around the second isolation opening 1201b and the first isolation portion 121 around the third isolation opening 1201c are etched to different degrees, resulting in the first overlapping length S1, the second overlapping length S2 and the third overlapping length S3 being different. In this embodiment, the first overlapping length S1, the second overlapping length S2, and the third overlapping length S3 decrease sequentially.

In another possible embodiment, the first isolation opening 1201a and the second isolation opening 1201b are formed at the same time, and after the first light-emitting device 13a is prepared within the first isolation opening 1201a, and the second light-emitting device 13b is prepared within the second isolation opening 1201b, the third isolation opening 1201c is formed. In this case, the first overlapping length S1 is the same as the third overlapping length S3 and greater than the second overlapping length S2.

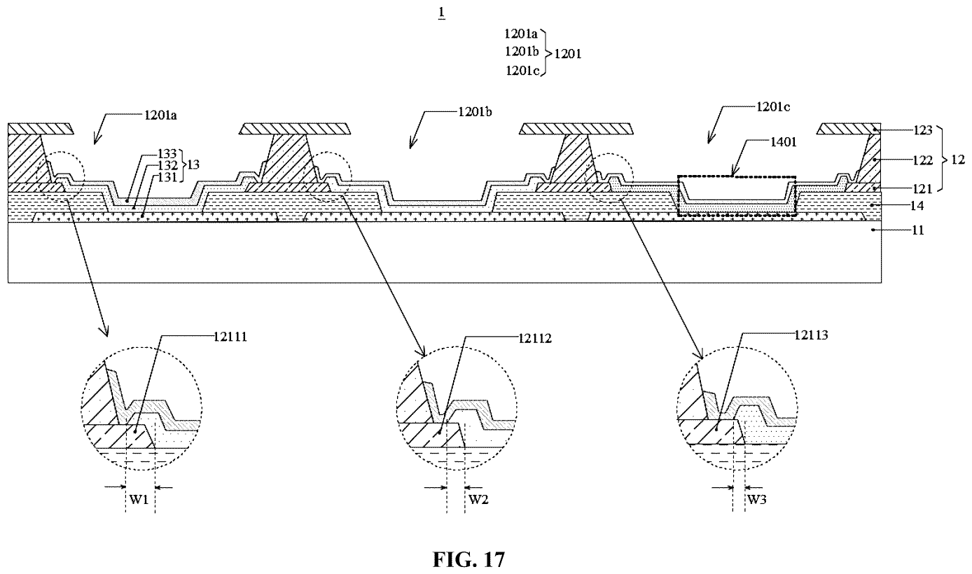

Referring to FIG. 17, in one or more embodiments, the orthographic projection of the light-emitting material layer 132 of the light-emitting device 13 on the substrate 11 partially overlaps the orthographic projection of the first isolation portion 121 on the substrate 11. Optionally, the first isolation portion 121 includes a protrusion portion 1211 protruding relative to the second isolation portion 122, and the orthographic projection of the light-emitting material layer 132 of the light-emitting device 13 on the substrate 11 partially overlaps the orthographic projection of the protrusion portion 1211 on the substrate 11. The light-emitting material layer 132 of the light-emitting device 13 lap-joins a part of the protrusion portion 1211, and the second electrode 133 of the light-emitting device 13 lap-joins another part of the protrusion portion 1211. The second electrode 133 may also lap-join one side of the second isolation portion 122 facing the isolation opening 1201 if the second electrode 133 extends beyond the protrusion portion 1211.

Within the first isolation opening 1201a, the first isolation portion 121 includes a first protrusion portion 12111 protruding relative to the second isolation portion 122. Within the second isolation opening 1201b, the first isolation portion 121 includes a second protrusion portion 12112 protruding relative to the second isolation portion 122. On the cross section perpendicular to the plane on which the substrate 11 is located and passing through the center connection line of the two adjacent isolation openings 1201, the light-emitting material layer 132 of the first light-emitting device 13a and the first protrusion portion 12111 have a first lap-joint length W1, and the light-emitting material layer 132 of the second light-emitting device 13b and the second protrusion portion 12112 have a second lap-joint length W2. It can be seen from the preceding description that the first distance d1 is different from the second distance d2. When the light-emitting material layer 132 is manufactured at the same evaporation angle, the first lap-joint length W1 is different from the second lap-joint length W2. When the first distance d1 is less than the second distance d2, the first lap-joint length W1 is greater than the second lap-joint length W2.

Referring to FIG. 17, within the third isolation opening 1201c, the first isolation portion 121 includes a third protrusion portion 12113 protruding relative to the second isolation portion 122. On the cross section perpendicular to the plane on which the substrate 11 is located and passing through the center connection line of the two adjacent isolation openings 1201, the light-emitting material layer 132 of the third light-emitting device 13c and the third protrusion portion 12113 have a third lap-joint length W3. It can be seen from the preceding description that the first distance d1, the second distance d2 and the third distance d3 are different. When the light-emitting material layer 132 is manufactured at the same evaporation angle, the first lap-joint length W1, the second lap-joint length W2, and the third lap-joint length W3 are different. When the first distance d1, the second distance d2, and the third distance d3 increase sequentially, the first lap-joint length W1, the second lap-joint length W2, and the third lap-joint length W3 decrease sequentially.

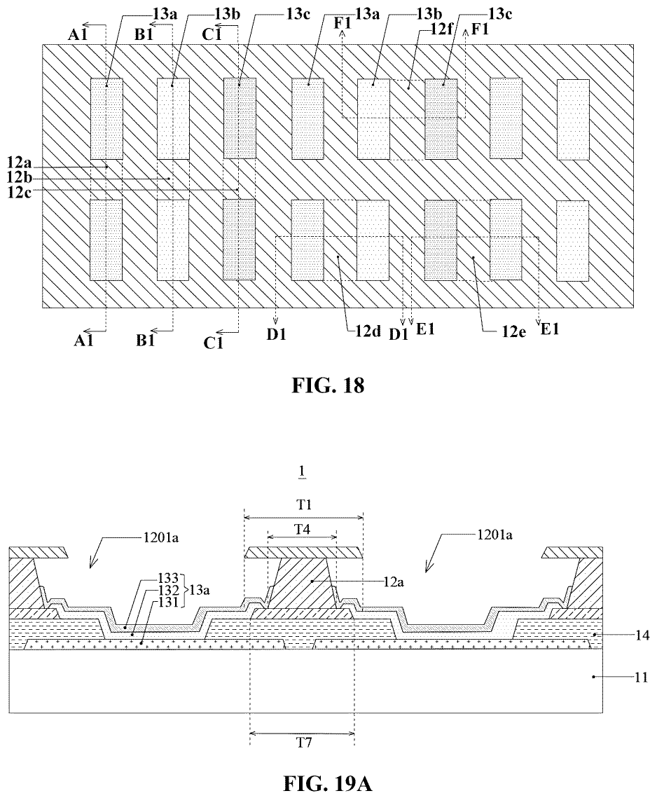

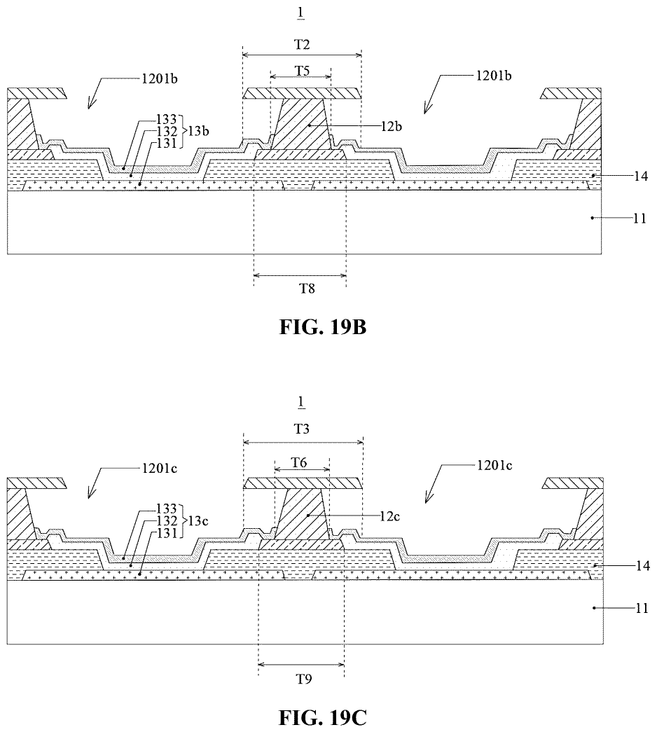

Referring to FIGS. 18 and 19A to 19C, FIG. 19A is a cross-sectional view of position A1A1 in FIG. 18, FIG. 19B is a cross-sectional view of position B1B1 in FIG. 18, and FIG. 19C is a cross-sectional view of position C1C1 in FIG. 18. The isolation structure 12 includes a first isolation structure 12a located between adjacent first isolation openings 1201a and a second isolation structure 12b located between adjacent second isolation openings 1201b. On the cross section perpendicular to the plane on which the substrate 11 is located and passing through the center connection line of the two adjacent isolation openings 1201, the orthographic projection of the third isolation portion 123 of the first isolation structure 12a on the substrate 11 has a first length T1, and the orthographic projection of the third isolation portion 123 of the second isolation structure 12b on the substrate 11 has a second length T2. The first length T1 is equal to the second length T2.

On the cross section perpendicular to the plane on which the substrate 11 is located and passing through the center connection line of the two adjacent isolation openings 1201, the orthographic projection of the second isolation portion 122 of the first isolation structure 12a on the substrate 11 has a fourth length T4, and the orthographic projection of the second isolation portion 122 of the second isolation structure 12b on the substrate 11 has a fifth length T5. The second isolation portion on the periphery of the first isolation opening 1201a is not cleaned, but the second isolation portion on the periphery of the second isolation opening 1201b is cleaned once, which reduces the length of the orthographic projection of the second isolation portion 122 on the substrate 11, resulting in the fourth length T4 and the fifth length T5 being unequal. Optionally, the fourth length T4 is greater than the fifth length T5.

On the cross section perpendicular to the plane on which the substrate 11 is located and passing through the center connection line of the two adjacent isolation openings 1201, the orthographic projection of the first isolation portion 121 of the first isolation structure 12a on the substrate 11 has a seventh length T7, and the orthographic projection of the first isolation portion 121 of the second isolation structure 12b on the substrate 11 has an eighth length T8. The seventh length T7 is not equal to the eighth length T8. Optionally, the seventh length T7 is greater than the eighth length T8.

Further, the isolation structure 12 further includes a third isolation structure 12c located between adjacent third isolation openings 1201c, and the orthographic projection of the third isolation portion 123 of the third isolation structure 12c on the substrate 11 has a third length T3. The first length T1, the second length T2, and the third length T3 are equal. The orthographic projection of the second isolation portion 122 of the third isolation structure 12c on the substrate 11 has a sixth length T6. The second isolation portion 122 on the periphery of the third isolation opening 1201c is cleaned twice, which reduces the length of the orthographic projection of the second isolation portion 122 on the substrate 11, resulting in the fourth length T4, the fifth length T5, and the sixth length T6 being unequal. Optionally, the fourth length T4, the fifth length T5, and the sixth length T6 decrease sequentially.

On the cross section perpendicular to the plane on which the substrate 11 is located and passing through the center connection line of the two adjacent isolation openings 1201, the orthographic projection of the first isolation portion 121 of the third isolation structure 12c on the substrate 11 has a ninth length T9. The seventh length T7, the eighth length T8, and the ninth length T9 are not equal. Optionally, the seventh length T7, the eighth length T8, and the ninth length T9 decrease sequentially.

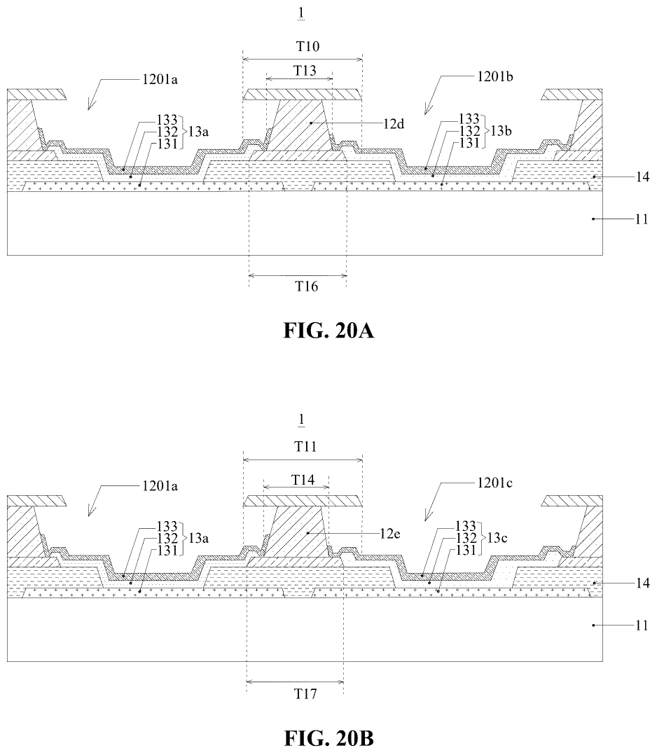

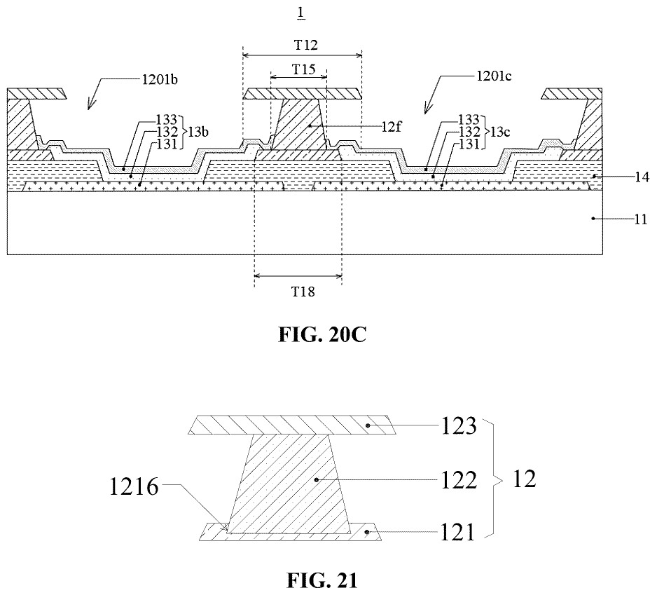

Further, referring to FIGS. 18 and 20A to 20C, FIG. 20A is a cross-sectional view of position D1D1 in FIG. 18, FIG. 20B is a cross-sectional view of position E1E1 in FIG. 18, and FIG. 20C is a cross-sectional view of position F1F1 in FIG. 18. The isolation structure 12 includes a fourth isolation structure 12d located between adjacent first isolation opening 1201a and second isolation opening 1201b, a fifth isolation structure 12e located between adjacent first isolation opening 1201a and third isolation opening 1201c and a sixth isolation structure 12f located between adjacent second isolation opening 1201b and third isolation opening 1201c.

On the cross section perpendicular to the plane on which the substrate 11 is located and passing through the center connection line of the two adjacent isolation openings 1201, the orthographic projection of the third isolation portion 123 of the fourth isolation structure 12d on the substrate 11 has a tenth length T10, the orthographic projection of the third isolation portion 123 of the fifth isolation structure 12e on the substrate 11 has an eleventh length T11, and the orthographic projection of the third isolation portion 123 of the sixth isolation structure 12f on the substrate 11 has a twelfth length T12. The tenth length T10, the eleventh length T11, and the twelfth length T12 are equal.

On the cross section perpendicular to the plane on which the substrate 11 is located and passing through the center connection line of the two adjacent isolation openings 1201, the orthographic projection of the second isolation portion 122 of the fourth isolation structure 12d on the substrate 11 has a thirteenth length T13, the orthographic projection of the second isolation portion 122 of the fifth isolation structure 12e on the substrate 11 has a fourteenth length T14, and the orthographic projection of the second isolation portion 122 of the sixth isolation structure 12f on the substrate 11 has a fifteenth length T15. The thirteenth length T13, the fourteenth length T14, and the fifteenth length T15 are not equal. Optionally, the thirteenth length T13, the fourteenth length T14, and the fifteenth length T15 decrease sequentially.

Referring to FIGS. 20A to 20C, on the cross section perpendicular to the plane on which the substrate 11 is located and passing through the center connection line of the two adjacent isolation openings 1201, the orthographic projection of the first isolation portion 121 of the fourth isolation structure 12d on the substrate 11 has a sixteenth length T16, the orthographic projection of the first isolation portion 121 of the fifth isolation structure 12e on the substrate 11 has a seventeenth length T17, and the orthographic projection of the first isolation portion 121 of the sixth isolation structure 12f on the substrate 11 has an eighteenth length T18. The sixteenth length T16, the seventeenth length T17, and the eighteenth length T18 are not equal. Optionally, the sixteenth length T16, the seventeenth length T17, and the eighteenth length T18 decrease sequentially.

Referring to FIG. 21, in this embodiment, one side of the first isolation portion 121 facing away from the substrate 11 may also be formed with a groove 1216, and a portion of the second isolation portion 122 facing the substrate 11 is located within the groove 1216, that is, the second isolation portion 122 may be partially embedded into the first isolation portion 121. Further, the bottom of the groove 1216 and the sidewall of the groove 1216 contact the second isolation portion 122. The preceding design can increase the contact area between the second isolation portion 122 and the first isolation portion 121 and reduce a connection resistance between the second isolation portion 122 and the first isolation portion 121, thereby improving the overall conductive performance of the isolation structure 12 but also reduce the area of the exposed sidewall of the second isolation portion 12, thereby reducing the impact of the exposed sidewall on the conductive performance due to oxidation.

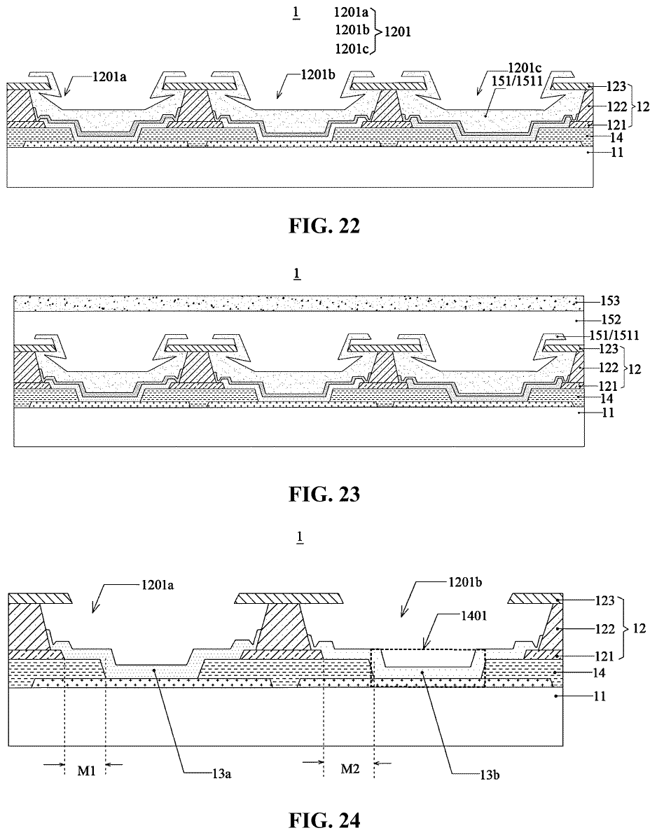

Further, referring to FIG. 22, in this embodiment, the display panel 1 further includes a first encapsulation layer 151. The first encapsulation layer 151 includes multiple encapsulation units 1511. Different encapsulation units 1511 are configured to encapsulate light-emitting devices 13 within different isolation openings 1201. Each encapsulation unit 1511 is configured to independently encapsulate the light-emitting device 13 within at least one isolation opening 1201. When light-emitting devices 13 within adjacent isolation openings 1201 have the same emitted color, two adjacent encapsulation units 1511 are connected to each other on one side of the isolation structure 12 facing away from the substrate 11. When the light-emitting devices 13 within the adjacent isolation openings 1201 have different emitted colors, the two adjacent encapsulation units 1511 are disconnected on the side of the isolation structure 12 facing away from the substrate 11, and a gap is present between each encapsulation unit 1511 located on the side of the isolation structure 12 facing away from the substrate 11 and the isolation structure 12. Optionally, in the direction perpendicular to the plane on which the substrate 11 is located, the thickness of the each encapsulation unit 1511 is more than two times the thickness of the first isolation portion 121, and the distribution of films of the each encapsulation unit 1511 is not uniform, that is, the thickness of any position of the each encapsulation unit 1511 is more than two times the thickness of the first isolation portion 121. The thickness of the films of the thinnest position of each encapsulation unit 1511 is more than two times the thickness of the first isolation portion 121 so that each encapsulation unit 1511 can effectively encapsulate a respective light-emitting device 13, thereby ensuring the effectiveness and reliability of the encapsulation.

Referring to FIG. 23, the display panel 1 further includes a second encapsulation layer 152 and a third encapsulation layer 153. The second encapsulation layer 152 covers the isolation structure 12 and the light-emitting devices 13. One side of the second encapsulation layer 152 facing away from the substrate 11 includes a flat surface. The third encapsulation layer 153 is located on the side of the second encapsulation layer 152 facing away from the substrate 11. The first encapsulation layer 151 and the third encapsulation layer 153 are inorganic encapsulation layers, and the second encapsulation layer 152 is an organic encapsulation layer. For example, the first encapsulation layer 151 and the third encapsulation layer 153 may be formed by chemical vapor deposition (CVD), and the second encapsulation layer 152 may be formed by inkjet printing (IJP). The first encapsulation layer 151, the second encapsulation layer 152, and the third encapsulation layer 153 form a thin-film encapsulation structure of the display panel 1.

It is to be understood that the display panel 1 may further include films sequentially stacked on one side of the third encapsulation layer 153 facing away from the substrate 11, such as a touch function layer, an optical adhesive layer, a polarizer, and a cover plate. The preceding films are conventional films of the display panel, and details are not repeated in detail herein.

Based on the same inventive concept, this embodiment further provides a display panel. Referring to FIG. 24, the display panel 1 includes a substrate 11, a pixel defining layer 14, an isolation structure 12, and light-emitting devices 13. The substrate 11 is a multilayer structure and at least includes multiple conductive layers and one or more insulating layers. At least one of the insulating layers is located between adjacent conductive layers. Pixel circuits for providing drive signals for the light-emitting devices are formed in the substrate 11. The multiple conductive layers may be metal conductive layers.

The pixel defining layer 14 is located on one side of the substrate 11 and includes a pixel opening 1401. The isolation structure 12 is located on one side of the pixel defining layer 14 facing away from the substrate 11. Multiple isolation openings 1201 are enclosed by the isolation structure 12 on the substrate 11. In the direction facing away from the substrate 11, the isolation structure 12 includes a first isolation portion 121, a second isolation portion 122, and a third isolation portion 123 that are sequentially stacked. The orthographic projection of the second isolation portion 122 on the substrate 11 is located within the orthographic projection of the first isolation portion 121 on the substrate 11 and within the orthographic projection of the third isolation portion 123 on the substrate 11. The orthographic projection of the pixel opening 1401 on the substrate 11 is located within the orthographic projection of an isolation opening 1201 on the substrate 11. On the cross section perpendicular to the plane on which the substrate 11 is located and in the direction of a center connection line of adjacent isolation openings 1201, the cross-sectional shape of the isolation structure 12 is I-shaped.

At least part of a light-emitting device of the light-emitting devices 13 is located within an isolation opening of the multiple isolation openings 1201. The light-emitting devices 13 include a first light-emitting device 13a and a second light-emitting device 13b that have different emitted colors. The multiple isolation openings 1201 include a first isolation opening 1201a and a second isolation opening 1201b. At least part of the first light-emitting device 13a is accommodated within the first isolation opening 1201a, and at least part of the second light-emitting device 13b is accommodated within the second isolation opening 1201b.

Within the first isolation opening 1201a, a first spacing M1 is present between one end of the first isolation portion 121 facing the pixel opening 1401 and the corresponding sidewall of the pixel opening 1401; within the second isolation opening 1201b, a second spacing M2 is present between the end of the first isolation portion 121 facing the pixel opening 1401 and the corresponding sidewall of the pixel opening 1401. Since the isolation structure 12 around the second isolation opening 1201b is etched once to remove films of the light-emitting devices in the multiple isolation openings, the first isolation portion 121 in the second isolation opening 1201b is partially etched, but no etching is performed on the isolation structure 12 around the first isolation opening 1201a to remove the films of the light-emitting devices in the multiple isolation openings, resulting in the first spacing M1 and the second spacing M2 being different. Optionally, the first spacing M1 is less than the second spacing M2.

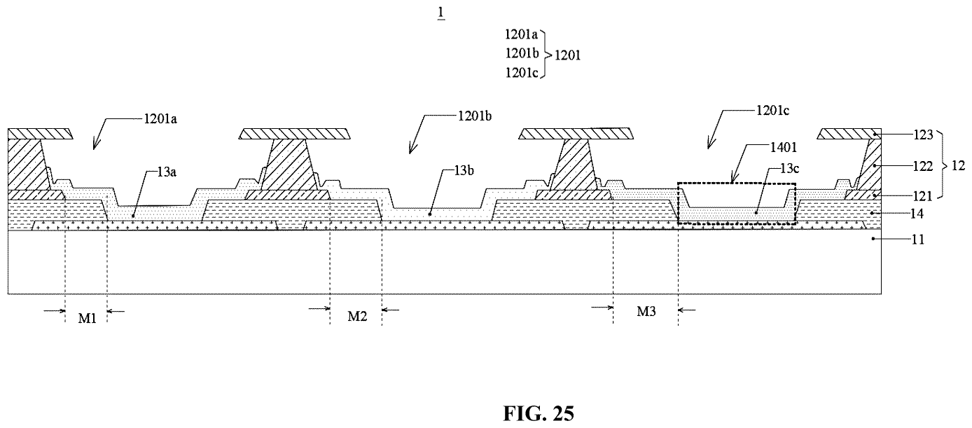

Referring to FIG. 25, the light-emitting devices 13 further include a third light-emitting device 13c. The third light-emitting device 13c has an emitted color different from the emitted colors of the first light-emitting device 13a and the second light-emitting device 13b. The multiple isolation openings 1201 further include a third isolation opening 1201c, and at least part of the third light-emitting device 13c is located within the third isolation opening 1201c. Within the third isolation opening 1201c, a third spacing M3 is present between the end of the first isolation portion 121 facing the pixel opening 1401 and the corresponding sidewall of the pixel opening 1401. The isolation structure 12b around the first isolation opening 1201a is not etched in the process of patterning the light-emitting devices, the isolation structure 12 around the second isolation opening 1201b is etched once to remove the films of the light-emitting devices in the multiple isolation openings 1201, and the isolation structure 12 around the third isolation opening 1201c is etched twice to remove the films of the light-emitting devices in the multiple isolation openings, resulting in at least two of the previously described first spacing M1, second spacing M2, and third spacing M3 unequal. In this embodiment, the first spacing M1, the second spacing M2, and the third spacing M3 increase sequentially.

In one or more possible embodiments, referring to FIGS. 7 and 8, a contour line of the orthographic projection of the third isolation portion 123 on the substrate 11 includes a first contour line 1231 corresponding to the first isolation opening 1201a and a second contour line 1232 corresponding to the second isolation opening 1201b. A contour line of the orthographic projection of the first isolation portion 121 on the substrate 11 includes a third contour line 1212 corresponding to the first isolation opening 1201a and a fourth contour line 1213 corresponding to the second isolation opening 1201b.

A first distance d1 is present between corresponding first contour line 1231 and third contour line 1212. A second distance d2 is present between corresponding second contour line 1232 and fourth contour line 1213. The first distance d1 is not equal to the second distance d2. Optionally, the first distance d1 is less than the second distance d2.

Further, referring to FIGS. 9 and 10, the contour line of the orthographic projection of the third isolation portion 123 on the substrate 11 includes a fifth contour line 1233 corresponding to the third isolation opening 1201c, and the contour line of the orthographic projection of the first isolation portion 121 on the substrate 11 includes a sixth contour line 1214 corresponding to the third isolation opening. A third distance d3 is present between corresponding fifth contour line 1233 and sixth contour line 1214. At least two of the first distance d1, the second distance d2, and the third distance d3 are not equal. Optionally, the first distance d1, the second distance d2, and the third distance d3 increase sequentially.

In one or more possible embodiments, referring to FIGS. 19A to 19C, the isolation structure 12 includes a first isolation structure 12a located between adjacent first isolation openings 1201a and a second isolation structure 12b located between adjacent second isolation openings 1201b. On the cross section perpendicular to the plane on which the substrate 11 is located and passing through a center connection line of two adjacent isolation openings 1201, the orthographic projection of the third isolation portion 123 of the first isolation structure 12a on the substrate 11 has a first length T1, and the orthographic projection of the third isolation portion 123 of the second isolation structure 12b on the substrate 11 has a second length T2. The first length T1 is equal to the second length T2.

On the cross section perpendicular to the plane on which the substrate 11 is located and passing through the center connection line of the two adjacent isolation openings 1201, the orthographic projection of the second isolation portion 122 of the first isolation structure 12a on the substrate 11 has a fourth length T4, and the orthographic projection of the second isolation portion 122 of the second isolation structure 12b on the substrate 11 has a fifth length T5. The second isolation portion around the first isolation opening 1201a is not cleaned, but the second isolation portion around the second isolation opening 1201b is cleaned once, which reduces the length of the orthographic projection of the second isolation portion 122 on the substrate 11, resulting in the fourth length T4 and the fifth length T5 being unequal. Optionally, the fourth length T4 is greater than the fifth length T5.

On the cross section perpendicular to the plane on which the substrate 11 is located and passing through the center connection line of the two adjacent isolation openings 1201, the orthographic projection of the first isolation portion 121 of the first isolation structure 12a on the substrate 11 has a seventh length T7, and the orthographic projection of the first isolation portion 121 of the second isolation structure 12b on the substrate 11 has an eighth length T8. The seventh length T7 is not equal to the eighth length T8. Optionally, the seventh length T7 is greater than the eighth length T8.

Further, the isolation structure 12 further includes a third isolation structure 12c located between adjacent third isolation openings 1201c, and the orthographic projection of the third isolation portion 123 of the third isolation structure 12c on the substrate 11 has a third length T3. The first length T1, the second length T2, and the third length T3 are equal. The orthographic projection of the second isolation portion 122 of the third isolation structure 12c on the substrate 11 has a sixth length T6. The second isolation portion 122 around the third isolation opening 1201c is cleaned twice, which reduces the length of the orthographic projection of the second isolation portion 122 on the substrate 11, resulting in at least two of the fourth length T4, the fifth length T5, and the sixth length T6 being unequal. Optionally, the fourth length T4, the fifth length T5, and the sixth length T6 decrease sequentially.

On the cross section perpendicular to the plane on which the substrate 11 is located and passing through the center connection line of the two adjacent isolation openings 1201, the orthographic projection of the first isolation portion 121 of the third isolation structure 12c on the substrate 11 has a ninth length T9. At least two of the seventh length T7, the eighth length T8, and the ninth length T9 are not equal. Optionally, the seventh length T7, the eighth length T8, and the ninth length T9 decrease sequentially.

Further, referring to FIGS. 20A to 20C, the isolation structure 12 includes a fourth isolation structure 12d located between adjacent first isolation opening 1201a and second isolation opening 1201b, a fifth isolation structure 12e located between adjacent first isolation opening 1201a and third isolation opening 1201c, and a sixth isolation structure 12f located between adjacent second isolation opening 1201b and third isolation opening 1201c.

On the cross section perpendicular to the plane on which the substrate 11 is located and passing through the center connection line of the two adjacent isolation openings 1201, the orthographic projection of the third isolation portion 123 of the fourth isolation structure 12d on the substrate 11 has a tenth length T10, the orthographic projection of the third isolation portion 123 of the fifth isolation structure 12e on the substrate 11 has an eleventh length T11, and the orthographic projection of the third isolation portion 123 of the sixth isolation structure 12f on the substrate 11 has a twelfth length T12. The tenth length T10, the eleventh length T11, and the twelfth length T12 are equal.

On the cross section perpendicular to the plane on which the substrate 11 is located and passing through the center connection line of the two adjacent isolation openings 1201, the orthographic projection of the second isolation portion 122 of the fourth isolation structure 12d on the substrate 11 has a thirteenth length T13, the orthographic projection of the second isolation portion 122 of the fifth isolation structure 12e on the substrate 11 has a fourteenth length T14, and the orthographic projection of the second isolation portion 122 of the sixth isolation structure 12f on the substrate 11 has a fifteenth length T15. At least two of the thirteenth length T13, the fourteenth length T14, and the fifteenth length T15 are not equal. Optionally, the thirteenth length T13, the fourteenth length T14, and the fifteenth length T15 decrease sequentially.

Referring to FIGS. 20A to 20C, on the cross section perpendicular to the plane on which the substrate 11 is located and passing through the center connection line of the two adjacent isolation openings 1201, the orthographic projection of the first isolation portion 121 of the fourth isolation structure 12d on the substrate 11 has a sixteenth length T16, the orthographic projection of the first isolation portion 121 of the fifth isolation structure 12e on the substrate 11 has a seventeenth length T17, and the orthographic projection of the first isolation portion 121 of the sixth isolation structure 12f on the substrate 11 has an eighteenth length T18. At least two of the sixteenth length T16, the seventeenth length T17, and the eighteenth length T18 are not equal. Optionally, the sixteenth length T16, the seventeenth length T17, and the eighteenth length T18 decrease sequentially.

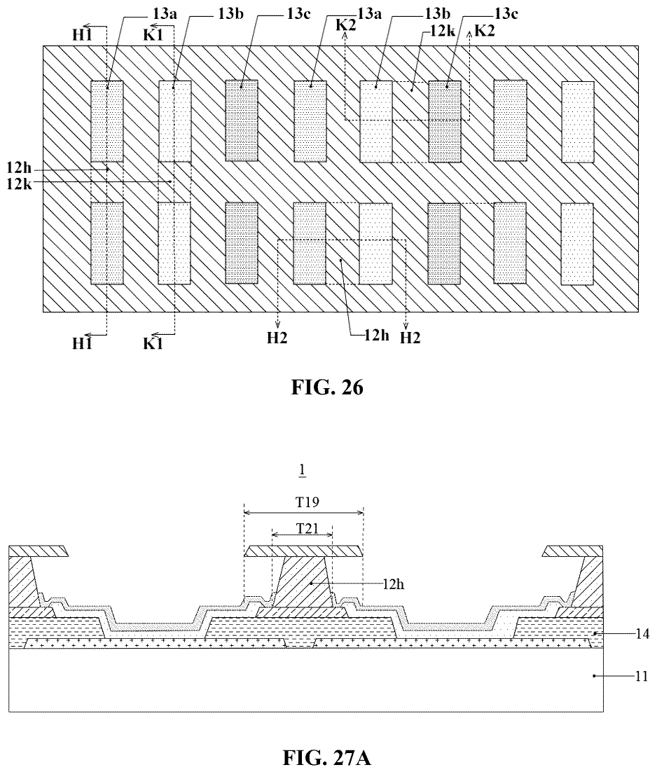

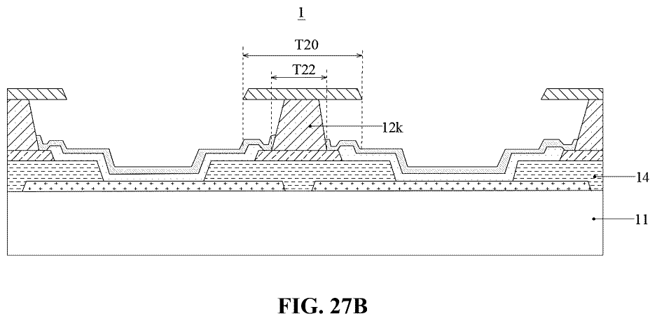

Based on the same inventive concept, this embodiment further provides a display panel. Referring to FIGS. 8, 26, 27A, and 27B, FIG. 27A is a cross-sectional view of position H1H1 and position H2H2 in FIG. 26. FIG. 27B is a cross-sectional view of position K1K1 and position K2K2 in FIG. 26. The display panel 1 includes a substrate 11, an isolation structure 12, and light-emitting devices 13. The substrate 11 is a multilayer structure and at least includes multiple conductive layers and one or more insulating layers. At least one of the insulating layers is located between adjacent conductive layers. Pixel circuits for providing drive signals for the light-emitting devices are formed in the substrate 11. The multiple conductive layers may be metal conductive layers.

The isolation structure 12 is located on one side of the substrate 11. Multiple isolation openings 1201 are enclosed by the isolation structure 12 on the substrate 11. In the direction facing away from the substrate 11, the isolation structure 12 includes a first isolation portion 121, a second isolation portion 122, and a third isolation portion 123 that are sequentially stacked. The orthographic projection of the second isolation portion 122 on the substrate 11 is located within the orthographic projection of the first isolation portion 121 on the substrate 11 and within the orthographic projection of the third isolation portion 123 on the substrate 11. On the cross section perpendicular to the plane on which the substrate 11 is located and in the direction of a center connection line of adjacent isolation openings, the cross-sectional shape of the isolation structure 12 is I-shaped.

At least part of a light-emitting device of the light-emitting devices 13 is located within an isolation opening 1201 of the multiple isolation openings 1201. The light-emitting devices 13 include a first light-emitting device 13a and a second light-emitting device 13b that have different emitted colors. The multiple isolation openings 1201 include a first isolation opening 1201a and a second isolation opening 1201b. At least part of the first light-emitting device 13a is accommodated within the first isolation opening 1201a, and at least part of the second light-emitting device 13b is accommodated within the second isolation opening 1201b.

The isolation structure 12 includes a seventh isolation structure 12h and an eighth isolation structure 12k. At least one light-emitting device 13 located within isolation openings 1201 on two opposite sides of the seventh isolation structure 12h and at least one light-emitting device 13 located within isolation openings 1201 on two opposite sides of the eighth isolation structure 12k have different emitted colors.

Referring to FIGS. 27A and 27B, on the cross section perpendicular to the plane on which the substrate 11 is located and passing through a center connection line of two adjacent isolation openings 1201, the orthographic projection of the third isolation portion 123 of the seventh isolation structure 12h on the substrate 11 has a nineteenth length T19, the orthographic projection of the third isolation portion 123 of the eighth isolation structure 12k on the substrate 11 has a twentieth length T20, the orthographic projection of the second isolation portion 122 of the seventh isolation structure 12h on the substrate 11 has a twenty-first length T21, and the orthographic projection of the second isolation portion 122 of the eighth isolation structure 12k on the substrate 11 has a twenty-second length T22. The nineteenth length T19 is the same as the twentieth length T20, and the twenty-first length T21 is different from the twenty-second length T22. Optionally, the twenty-first length T21 is greater than the twenty-second length T22.

In one or more embodiments, the seventh isolation structure 12h is located between adjacent first isolation openings 1201a, and the eighth isolation structure 12k is located between adjacent second isolation openings 1201b; or the seventh isolation structure 12h is located between adjacent first isolation opening 1201a and second isolation opening 1201b, and the eighth isolation structure 12k is located between adjacent same isolation openings 1201. When the seventh isolation structure 12h is located between the adjacent first isolation opening 1201a and second isolation opening 1201b, and the eighth isolation structure 12k is located between the adjacent same isolation openings 1201, light-emitting devices 13 located within the isolation openings 1201 on the two opposite sides of the seventh isolation structure 12h have different emitted colors, and light-emitting devices 13 located within the isolation openings 1201 on the two opposite sides of the eighth isolation structure 12k have the same emitted color.

Further, referring to FIGS. 10, 26, 27A, and 27B, in this embodiment, the light-emitting devices 13 further include a third light-emitting device 13c having an emitted color different from the emitted color of the first light-emitting device 13a and the emitted color of the second light-emitting device 13b. The multiple isolation openings 1201 further include a third isolation opening 1201c, and the third light-emitting device 13c is manufactured within the third isolation opening 1201c. The seventh isolation structure 12h may be located between the adjacent first isolation opening 1201a and second isolation opening 1201b, and the eighth isolation structure 12k may be located between adjacent second isolation opening 1201b and third isolation opening 1201c.

Based on the same inventive concept, the present application further provides an electronic device. The electronic device includes the display panel provided in the present application or a display panel prepared using the preparation method for a display panel provided in this embodiment. The electronic device may include a mobile phone, a tablet computer, a smart wearable device, a television, a laptop computer, a monitor, or another device with a display function.

The preceding embodiments are several embodiments of the present application, and the specific and detailed description thereof cannot be understood as limiting the scope of the present application. It is to be noted that for those of ordinary skill in the art, several modifications and improvements can be made without departing from the concept of the present application, and these modifications and improvements are within the scope of the present application. Therefore, the protection scope of the present application is defined by the appended claims.

What is claimed is:

1. A preparation method for a display panel, comprising:
providing a substrate;
forming an isolation structure on one side of the substrate, wherein the isolation structure is provided with a plurality of isolation openings, and in a direction facing away from the substrate, the isolation structure comprises a first isolation portion, a second isolation portion and a third isolation portion that are sequentially stacked, wherein an orthographic projection of the second isolation portion on the substrate is located within an orthographic projection of the third isolation portion on the substrate;
cleaning the second isolation portion in the isolation structure to enable the first isolation portion to have a protrusion portion protruding relative to the second isolation portion in a direction facing an isolation opening of the plurality of isolation openings; and
manufacturing a light-emitting device within the isolation opening of the plurality of isolation openings to enable at least part of films of the light-emitting device to lap-join the protrusion portion.

2. The preparation method for a display panel of claim 1, wherein the display panel comprises a first light-emitting device and a second light-emitting device that have different emitted colors, and the plurality of isolation openings comprise a first isolation opening and a second isolation opening, wherein within the first isolation opening, the first isolation portion has a first protrusion portion protruding relative to the second isolation portion;
before cleaning the second isolation portion in the isolation structure to enable the first isolation portion to have the protrusion portion protruding relative to the second isolation portion in the direction facing the isolation opening of the plurality of isolation openings, the method comprises:
manufacturing films of the first light-emitting device within the first isolation opening and the second isolation opening, wherein within the first isolation opening, at least part of the films of the first light-emitting device lap-join the first protrusion portion; and
etching and removing the films of the first light-emitting device within the second isolation opening;
wherein cleaning the second isolation portion in the isolation structure to enable the first isolation portion to have the protrusion portion protruding relative to the second isolation portion in the direction facing the isolation opening of the plurality of isolation openings comprises:
cleaning the second isolation portion on a periphery of the second isolation opening using an etching solution to enable the first isolation portion to have a second protrusion portion protruding relative to the second isolation portion within the second isolation opening; and
wherein manufacturing the light-emitting device within the isolation opening of the plurality of isolation openings to enable the at least part of the films of the light-emitting device to lap-join the protrusion portion comprises:
manufacturing films of the second light-emitting device within the second isolation opening, wherein within the second isolation opening, at least part of the films of the second light-emitting device lap-join the second protrusion portion.

3. The preparation method for a display panel of claim 2, wherein the display panel further comprises a third light-emitting device having an emitted color different from the emitted colors of the first light-emitting device and the second light-emitting device, and the plurality of isolation openings further comprise a third isolation opening;
after manufacturing the films of the second light-emitting device within the second isolation opening, cleaning the second isolation portion in the isolation structure to enable the first isolation portion to have the protrusion portion protruding relative to the second isolation portion in the direction facing the isolation opening of the plurality of isolation openings further comprises:
etching and removing the films of the second light-emitting device manufactured at the third isolation opening; and
cleaning the second isolation portion on a periphery of the third isolation opening using the etching solution to enable the first isolation portion to have a third protrusion portion protruding relative to the second isolation portion within the third isolation opening; and
wherein manufacturing the light-emitting device within the isolation opening of the plurality of isolation openings to enable the at least part of the films of the light-emitting device to lap-join the protrusion portion further comprises:
manufacturing at least part of films of the third light-emitting device within the third isolation opening, wherein within the third isolation opening, the at least part of the films of the third light-emitting device lap-join the third protrusion portion.

4. A display panel, comprising:
a substrate;
an isolation structure located on one side of the substrate, wherein a plurality of isolation openings are enclosed by the isolation structure on the substrate, and in a direction facing away from the substrate, the isolation structure comprises a first isolation portion, a second isolation portion and a third isolation portion that are sequentially stacked, wherein an orthographic projection of the second isolation portion on the substrate is located within an orthographic projection of the first isolation portion on the substrate and within an orthographic projection of the third isolation portion on the substrate; and
light-emitting devices, wherein at least part of a light-emitting device of the light-emitting devices is located within an isolation opening of the plurality of isolation opening, the light-emitting devices comprise a first light-emitting device and a second light-emitting device that have different emitted colors, and the plurality of isolation openings comprise a first isolation opening for accommodating the first light-emitting device and a second isolation opening for accommodating the second light-emitting device,
wherein a contour line of the orthographic projection of the third isolation portion on the substrate comprises a first contour line corresponding to the first isolation opening and a second contour line corresponding to the second isolation opening, and a contour line of the orthographic projection of the first isolation portion on the substrate comprises a third contour line corresponding to the first isolation opening and a fourth contour line corresponding to the second isolation opening; and
wherein a distance between corresponding first contour line and third contour line is a first distance, a distance between corresponding second contour line and fourth contour line is a second distance, and the first distance is not equal to the second distance.

5. The display panel of claim 4, wherein the first distance is less than the second distance;
the light-emitting devices further comprise a third light-emitting device having an emitted color different from the emitted colors of the first light-emitting device and the second light-emitting device;
the plurality of isolation openings further comprise a third isolation opening, wherein at least part of the third light-emitting device is located within the third isolation opening;
the contour line of the orthographic projection of the third isolation portion on the substrate comprises a fifth contour line corresponding to the third isolation opening, and the contour line of the orthographic projection of the first isolation portion on the substrate comprises a sixth contour line corresponding to the third isolation opening, wherein a distance between corresponding fifth contour line and sixth contour line is a third distance; wherein the first distance, the second distance and the third distance are not equal; and
the first distance, the second distance, and the third distance increase sequentially.

6. The display panel of claim 4, wherein within the first isolation opening, the first isolation portion has a first protrusion length relative to the second isolation portion; within the second isolation opening, the first isolation portion has a second protrusion length relative to the second isolation portion; and
the first protrusion length and the second protrusion length are each less than or equal to 0.3 μm.

7. The display panel of claim 6, wherein the light-emitting devices further comprise a third light-emitting device having an emitted color different from the emitted colors of the first light-emitting device and the second light-emitting device; and
the plurality of isolation openings further comprise a third isolation opening, wherein at least part of the third light-emitting device is located within the third isolation opening; within the third isolation opening, the first isolation portion has a third protrusion length relative to the second isolation portion;
wherein one of the following configurations is satisfied:
the first protrusion length is greater than or equal to the second protrusion length, and the second protrusion length is equal to the third protrusion length;
the first protrusion length is equal to the third protrusion length and greater than or equal to the second protrusion length; and
the first protrusion length, the second protrusion length, and the third protrusion length are equal.

8. The display panel of claim 4, wherein within the first isolation opening, the third isolation portion has a fourth protrusion length relative to a bottom on one side of the second isolation portion facing the substrate; within the second isolation opening, the third isolation portion has a fifth protrusion length relative to the bottom on the side of the second isolation portion facing the substrate, wherein the fourth protrusion length is not equal to the fifth protrusion length; and
the fourth protrusion length is less than the fifth protrusion length.

9. The display panel of claim 8, wherein the fourth protrusion length ranges from 0.1 μm to 0.6 μm, and the fifth protrusion length ranges from 0.2 μm to 0.9 μm.

10. The display panel of claim 8, wherein the light-emitting devices further comprise a third light-emitting device having an emitted color different from the emitted colors of the first light-emitting device and the second light-emitting device, and the plurality of isolation openings further comprise a third isolation opening, wherein at least part of the third light-emitting device is located within the third isolation opening; within the third isolation opening, the third isolation portion has a sixth protrusion length relative to the bottom on the side of the second isolation portion facing the substrate;
the sixth protrusion length ranges from 0.3 μm to 1.2 μm; and
the fourth protrusion length, the fifth protrusion length, and the sixth protrusion length increase sequentially.

11. The display panel of claim 4, wherein within the first isolation opening, the third isolation portion has a seventh protrusion length relative to a top on one side of the second isolation portion facing away from the substrate; within the second isolation opening, the third isolation portion has an eighth protrusion length relative to the top on the side of the second isolation portion facing away from the substrate, wherein the seventh protrusion length is not equal to the eighth protrusion length; and
the seventh protrusion length is less than the eighth protrusion length.

12. The display panel of claim 11, wherein the light-emitting devices further comprise a third light-emitting device having an emitted color different from the emitted colors of the first light-emitting device and the second light-emitting device, and the plurality of isolation openings further comprise a third isolation opening, wherein at least part of the third light-emitting device is located within the third isolation opening; within the third isolation opening, the third isolation portion has a ninth protrusion length relative to the top on the side of the second isolation portion facing away from the substrate; and
the seventh protrusion length, the eighth protrusion length, and the ninth protrusion length increase sequentially.

13. The display panel of claim 4, wherein in the direction facing away from the substrate, a light-emitting device of the light-emitting devices comprises a light-emitting material layer and a device function layer, wherein the device function layer comprises at least one of a second electrode and a light extraction layer;
the device function layer lap-joins one side of the second isolation portion facing an isolation opening of the plurality of isolation openings; and
in a direction perpendicular to a plane on which the substrate is located, a distance from a highest point at which the device function layer lap-joins the second isolation portion to the plane on which the substrate is located is a lap-joint height of the device function layer and the second isolation portion, a lap-joint height of the device function layer of the first light-emitting device and the second isolation portion is a first lap-joint height, and a lap-joint height of the device function layer of the second light-emitting device and the second isolation portion is a second lap-joint height, wherein the first lap-joint height is greater than the second lap-joint height.

14. The display panel of claim 13, wherein the light-emitting devices further comprise a third light-emitting device having an emitted color different from the emitted colors of the first light-emitting device and the second light-emitting device, and the plurality of isolation openings further comprise a third isolation opening, wherein at least part of the third light-emitting device is located within the third isolation opening; a lap-joint height of the device function layer of the third light-emitting device and the second isolation portion is a third lap-joint height; and
the first lap-joint height, the second lap-joint height, and the third lap-joint height decrease sequentially.

15. The display panel of claim 4, wherein a light-emitting device of the light-emitting devices comprises a first electrode connected to a pixel circuit in the substrate;
an orthographic projection of the first electrode of the light-emitting device on the substrate partially overlaps an orthographic projection of the first isolation portion on the substrate;
on a cross section perpendicular to a plane on which the substrate is located and passing through a center connection line of two adjacent isolation openings, an orthographic projection of the first electrode of the first light-emitting device on the substrate and an orthographic projection of the first isolation portion on the substrate have a first overlapping length, and an orthographic projection of the first electrode of the second light-emitting device on the substrate and the orthographic projection of the first isolation portion on the substrate have a second overlapping length; and
the light-emitting devices further comprise a third light-emitting device having an emitted color different from the emitted colors of the first light-emitting device and the second light-emitting device, and the plurality of isolation openings further comprise a third isolation opening, wherein at least part of the third light-emitting device is located within the third isolation opening; on the cross section perpendicular to the plane on which the substrate is located and passing through the center connection line of the two adjacent isolation openings, an orthographic projection of the first electrode of the third light-emitting device on the substrate and the orthographic projection of the first isolation portion on the substrate have a third overlapping length, wherein the first overlapping length, the second overlapping length, and the third overlapping length are different.

16. The display panel of claim 4, wherein an orthographic projection of a light-emitting material layer of a light-emitting device of the light-emitting devices on the substrate partially overlaps the orthographic projection of the first isolation portion on the substrate;
the first isolation portion comprises a protrusion portion protruding relative to the second isolation portion, and the orthographic projection of the light-emitting material layer of the light-emitting device on the substrate partially overlaps an orthographic projection of the protrusion portion on the substrate;
the light-emitting device further comprises a second electrode; the light-emitting material layer lap-joins a part of the protruding portion, and the second electrode lap-joins another part of the protruding portion; and
within the first isolation opening, the first isolation portion comprises a first protrusion portion protruding relative to the second isolation portion; within the second isolation opening, the first isolation portion comprises a second protrusion portion protruding relative to the second isolation portion; on a cross section perpendicular to a plane on which the substrate is located and passing through a center connection line of two adjacent isolation openings, the light-emitting material layer of the first light-emitting device and the first protrusion portion have a first lap-joint length, and the light-emitting material layer of the second light-emitting device and the second protrusion portion have a second lap-joint length.

17. The display panel of claim 16, wherein the light-emitting devices further comprise a third light-emitting device having an emitted color different from the emitted colors of the first light-emitting device and the second light-emitting device, and the plurality of isolation openings further comprise a third isolation opening, wherein at least part of the third light-emitting device is located within the third isolation opening; within the third isolation opening, the first isolation portion has a third protrusion portion protruding relative to the second isolation portion, and on the cross section perpendicular to the plane on which the substrate is located and passing through the center connection line of the two adjacent isolation openings, the light-emitting material layer of the third light-emitting device and the third protrusion portion have a third lap-joint length, wherein the first lap-joint length, the second lap-joint length, and the third lap-joint length are different.

18. The display panel of claim 4, wherein the isolation structure comprises a first isolation structure located between adjacent first isolation openings and a second isolation structure located between adjacent second isolation openings;
on a cross section perpendicular to a plane on which the substrate is located and passing through a center connection line of two adjacent isolation openings, an orthographic projection of the third isolation portion of the first isolation structure on the substrate has a first length, and an orthographic projection of the third isolation portion of the second isolation structure on the substrate has a second length, wherein the first length is equal to the second length;
on the cross section perpendicular to the plane on which the substrate is located and passing through the center connection line of the two adjacent isolation openings, an orthographic projection of the second isolation portion of the first isolation structure on the substrate has a fourth length, and an orthographic projection of the second isolation portion of the second isolation structure on the substrate has a fifth length, wherein the fourth length is not equal to the fifth length; and
on the cross section perpendicular to the plane on which the substrate is located and passing through the center connection line of the two adjacent isolation openings, an orthographic projection of the first isolation portion of the first isolation structure on the substrate has a seventh length, and an orthographic projection of the first isolation portion of the second isolation structure on the substrate has an eighth length, wherein the seventh length is not equal to the eighth length.

19. The display panel of claim 18, wherein the light-emitting devices further comprise a third light-emitting device having an emitted color different from the emitted colors of the first light-emitting device and the second light-emitting device, and the plurality of isolation openings further comprise a third isolation opening, wherein at least part of the third light-emitting device is located within the third isolation opening; the isolation structure further comprises a third isolation structure located between adjacent third isolation openings; an orthographic projection of the third isolation portion of the third isolation structure on the substrate has a third length, wherein the first length, the second length and the third length are equal;
an orthographic projection of the second isolation portion of the third isolation structure on the substrate has a sixth length, wherein the fourth length, the fifth length, and the sixth length are not equal; and
on the cross section perpendicular to the plane on which the substrate is located and passing through the center connection line of the two adjacent isolation openings, an orthographic projection of the first isolation portion of the third isolation structure on the substrate has a ninth length, wherein the seventh length, the eighth length, and the ninth length are not equal.

20. The display panel of claim 4, wherein the light-emitting devices further comprise a third light-emitting device having an emitted color different from the emitted colors of the first light-emitting device and the second light-emitting device, and the plurality of isolation openings further comprise a third isolation opening, wherein at least part of the third light-emitting device is located within the third isolation opening; the isolation structure comprises a fourth isolation structure located between adjacent first isolation opening and second isolation opening, a fifth isolation structure located between adjacent first isolation opening and third isolation opening and a sixth isolation structure located between adjacent second isolation opening and third isolation opening;
on a cross section perpendicular to a plane on which the substrate is located and passing through a center connection line of two adjacent isolation openings, an orthographic projection of the third isolation portion of the fourth isolation structure on the substrate has a tenth length, an orthographic projection of the third isolation portion of the fifth isolation structure on the substrate has an eleventh length, and an orthographic projection of the third isolation portion of the sixth isolation structure on the substrate has a twelfth length, wherein the tenth length, the eleventh length, and the twelfth length are equal;
on the cross section perpendicular to the plane on which the substrate is located and passing through the center connection line of the two adjacent isolation openings, an orthographic projection of the second isolation portion of the fourth isolation structure on the substrate has a thirteenth length, an orthographic projection of the second isolation portion of the fifth isolation structure on the substrate has a fourteenth length, and an orthographic projection of the second isolation portion of the sixth isolation structure on the substrate has a fifteenth length, wherein the thirteenth length, the fourteenth length, and the fifteenth length are not equal; and
on the cross section perpendicular to the plane on which the substrate is located and passing through the center connection line of the two adjacent isolation openings, an orthographic projection of the first isolation portion of the fourth isolation structure on the substrate has a sixteenth length, an orthographic projection of the first isolation portion of the fifth isolation structure on the substrate has a seventeenth length, and an orthographic projection of the first isolation portion of the sixth isolation structure on the substrate has an eighteenth length, wherein the sixteenth length, the seventeenth length, and the eighteenth length are not equal.

21. A display panel, comprising:
a substrate;
a pixel defining layer located on one side of the substrate and comprising a plurality of pixel openings;
an isolation structure located on one side of the pixel defining layer facing away from the substrate, wherein a plurality of isolation openings are enclosed by the isolation structure on the substrate, and in a direction facing away from the substrate, the isolation structure comprises a first isolation portion, a second isolation portion and a third isolation portion that are sequentially stacked, wherein an orthographic projection of the second isolation portion on the substrate is located within an orthographic projection of the first isolation portion on the substrate and within an orthographic projection of the third isolation portion on the substrate, and an orthographic projection of a pixel opening of the plurality pixel openings on the substrate is located within an orthographic projection of an isolation opening of the plurality of isolation openings on the substrate; and
light-emitting devices, wherein at least part of a light-emitting device of the light-emitting devices is located within an isolation opening of the plurality of isolation openings, the light-emitting devices comprise a first light-emitting device and a second light-emitting device that have different emitted colors, and the plurality of isolation openings comprise a first isolation opening for accommodating the first light-emitting device and a second isolation opening for accommodating the second light-emitting device,
within the first isolation opening, a spacing between one end of the first isolation portion facing a pixel opening and a corresponding sidewall of the pixel opening is a first spacing; within the second isolation opening, a spacing between the end of the first isolation portion facing a pixel opening and a corresponding sidewall of the pixel opening is a second spacing; and
wherein the first spacing is different from the second spacing.

22. The display panel of claim 21, wherein the first spacing is less than the second spacing; and
the light-emitting devices further comprise a third light-emitting device having an emitted color different from the emitted colors of the first light-emitting device and the second light-emitting device, and the plurality of isolation openings further comprise a third isolation opening, wherein at least part of the third light-emitting device is located within the third isolation opening; within the third isolation opening, a spacing between the end of the first isolation portion facing the pixel opening and a corresponding sidewall of a pixel opening is a third spacing, wherein the first spacing, the second spacing, and the third spacing are different.

23. The display panel of claim 22, wherein a contour line of the orthographic projection of the third isolation portion on the substrate comprises a first contour line corresponding to the first isolation opening and a second contour line corresponding to the second isolation opening, and a contour line of the orthographic projection of the first isolation portion on the substrate comprises a third contour line corresponding to the first isolation opening and a fourth contour line corresponding to the second isolation opening; and
a distance between corresponding first contour line and third contour line is a first distance, and a distance between corresponding second contour line and fourth contour line is a second distance, wherein the first distance is not equal to the second distance.

24. The display panel of claim 23, wherein the light-emitting devices further comprise the third light-emitting device having the emitted color different from the emitted colors of the first light-emitting device and the second light-emitting device, and the plurality of isolation openings further comprise the third isolation opening, wherein the at least part of the third light-emitting device is located within the third isolation opening; the contour line of the orthographic projection of the third isolation portion on the substrate comprises a fifth contour line corresponding to the third isolation opening, and the contour line of the orthographic projection of the first isolation portion on the substrate comprises a sixth contour line corresponding to the third isolation opening, wherein a distance between corresponding fifth contour line and sixth contour line is a third distance; wherein at least two of the first distance, the second distance, and the third distance are not equal.

25. The display panel of claim 21, wherein the isolation structure comprises a first isolation structure located between adjacent first isolation openings and a second isolation structure located between adjacent second isolation openings;
on a cross section perpendicular to a plane on which the substrate is located and passing through a center connection line of two adjacent isolation openings, an orthographic projection of the third isolation portion of the first isolation structure on the substrate has a first length, and an orthographic projection of the third isolation portion of the second isolation structure on the substrate has a second length, wherein the first length is equal to the second length; and
the light-emitting devices further comprise a third light-emitting device having an emitted color different from the emitted colors of the first light-emitting device and the second light-emitting device, and the plurality of isolation openings further comprise a third isolation opening, wherein at least part of the third light-emitting device is located within the third isolation opening; the isolation structure further comprises a third isolation structure located between adjacent third isolation openings; an orthographic projection of the third isolation portion of the third isolation structure on the substrate has a third length, wherein the first length, the second length, and the third length are equal.

26. The display panel of claim 25, wherein on the cross section perpendicular to the plane on which the substrate is located and passing through the center connection line of the two adjacent isolation openings, an orthographic projection of the second isolation portion of the first isolation structure on the substrate has a fourth length, and an orthographic projection of the second isolation portion of the second isolation structure on the substrate has a fifth length; and
an orthographic projection of the second isolation portion of the third isolation structure on the substrate has a sixth length, wherein the fourth length, the fifth length, and the sixth length decrease sequentially.

27. The display panel of claim 25, wherein on the cross section perpendicular to the plane on which the substrate is located and passing through the center connection line of the two adjacent isolation openings, an orthographic projection of the first isolation portion of the first isolation structure on the substrate has a seventh length, and an orthographic projection of the first isolation portion of the second isolation structure on the substrate has an eighth length; and
on the cross section perpendicular to the plane on which the substrate is located and passing through the center connection line of the two adjacent isolation openings, an orthographic projection of the first isolation portion of the third isolation structure on the substrate has a ninth length, wherein the seventh length, the eighth length and the ninth length decrease sequentially.

28. The display panel of claim 25, wherein the isolation structure comprises a fourth isolation structure located between adjacent first isolation opening and second isolation opening, a fifth isolation structure located between adjacent first isolation opening and third isolation opening and a sixth isolation structure located between adjacent second isolation opening and third isolation opening;
on the cross section perpendicular to the plane on which the substrate is located and passing through the center connection line of the two adjacent isolation openings, an orthographic projection of the third isolation portion of the fourth isolation structure on the substrate has a tenth length, an orthographic projection of the third isolation portion of the fifth isolation structure on the substrate has an eleventh length, and an orthographic projection of the third isolation portion of the sixth isolation structure on the substrate has a twelfth length, wherein the tenth length, the eleventh length and the twelfth length are equal;
on the cross section perpendicular to the plane on which the substrate is located and passing through the center connection line of the two adjacent isolation openings, an orthographic projection of the second isolation portion of the fourth isolation structure on the substrate has a thirteenth length, an orthographic projection of the second isolation portion of the fifth isolation structure on the substrate has a fourteenth length, and an orthographic projection of the second isolation portion of the sixth isolation structure on the substrate has a fifteenth length, wherein the thirteenth length, the fourteenth length and the fifteenth length decrease sequentially; and
on the cross section perpendicular to the plane on which the substrate is located and passing through the center connection line of the two adjacent isolation openings, an orthographic projection of the first isolation portion of the fourth isolation structure on the substrate has a sixteenth length, an orthographic projection of the first isolation portion of the fifth isolation structure on the substrate has a seventeenth length, and an orthographic projection of the first isolation portion of the sixth isolation structure on the substrate has an eighteenth length, wherein the sixteenth length, the seventeenth length and the eighteenth length decrease sequentially.
